(19) United States
(12) Patent Application Publication
(10) Pub. No.: US 2025/0380483 A1
(43) Pub. Date: Dec. 11, 2025

(54) TRANSISTOR STRUCTURE AND METHOD FOR FORMING THE SAME

(71) Applicant: Invention and Collaboration Laboratory, Inc., Taipei City (TW)

(72) Inventors: Chao-Chun LU, Hsinchu (TW); Li-Ping HUANG, Hsinchu (TW); Wen-Hsien TU, Hsinchu (TW)

(73) Assignee: Invention and Collaboration Laboratory, Inc., Taipei City (TW)

(21) Appl. No.: 18/964,216

(22) Filed: Nov. 29, 2024

Related U.S. Application Data
(60) Provisional application No. 63/658,863, filed on Jun. 11, 2024.

(51) Int. Cl. H10D 64/27; H01L 21/762; H10D 30/60; H10D 62/10; H10D 64/01

(52) U.S. Cl. CPC H10D 64/513; H01L 21/76224; H10D 30/608; H10D 62/124; H10D 64/017

(57) ABSTRACT

A transistor structure includes a semiconductor convex structure and a gate structure with a gate conductive layer and a gate dielectric layer. A set of trenches are formed in the semiconductor convex structure. The gate conductive layer is across over the semiconductor convex structure, and a portion of the gate conductive layer is filled in the set of trenches.

This application claims the benefit of U.S. provisional application Ser. No. 63/658,863 filed Jun. 11, 2024 and the subject matter of which is incorporated herein by reference.

### BACKGROUND OF THE DISCLOSURE

### Field of the Disclosure

The present invention relates to a semiconductor device and method for manufacturing the same, and particularly to a transistor structure and method for manufacturing the same.

### Description of the Related Art

Monolithic integration of Silicon devices for integrated circuits (IC) has achieved realization of more than 50 billions of transistors on a die in the year of 2021, which has been named as an era of GSI (Gigabyte-Scale Integration, i.e. Achieving more than billions of transistors on a die) from VLSI (Very Large Scale Integration having more than millions of transistors on a die). Such accomplishments of making much higher integration capacity of transistors on a die have sharply enabled more powerful Microsystems with significantly improved PPAC (higher Performance, better Power Managing capability, effective usage of Area and lower Cost per bit), thus creating many powerful chips such as CPU, GPU, FPGA, SOC, SRAM, DRAM, etc., which enhances System capabilities so as to continually support Moore's Law which formed a base to create an exponential Economic growth.

With such a high productivity generated from GSI to grow new applications which stimulates fast growth of economic scale, there are very strong demands to integrate more transistors on a die. So it is expected that Semiconductor industry try every best efforts to march toward a TSI, Tera-Scale Integration, that is, Integration of more than trillions of transistors on a die for a chip. Therefore, how to sharply improve the transistor to meet this TSI challenge requires Inventions and engineering improvements of for some fundamentally changed transistor structure with better PPAC. For example, if a chip does integrate one trillion transistors on a die, if each transistor is set at achieving a standby current (or called loff) about 0.5 pA (abbreviation of Ampere), then a total of one trillion of transistors will have its loff of a die is approaching 0.5 Amperes.

The state-of-art transistor with less than 20 nm technologies can hardly achieved this loff of 0.5 pA, however; even by using various transistor structures such as fin-field-effect transistor (FinFET) or Tri-Gate Designs, some loff can be as large as 5 to 10 pA. How to continuously shrink the device dimensions plus to reduce loff (such as lower than 1 pA) is the key challenge.

State-of-the-art finFET usually includes an active region which is formed as a fin structure. The transistor gate structure using some conductive material (like metal, polysilicon or polyside, etc.) over an insulator or dielectric layer (such as oxide, oxide/nitride or some high-k dielectric, etc.) is formed on a Fin-structure or a 3D silicon surface whose sidewalls are isolated from those of other transistors by using insulation materials (e.g. oxide or oxide/nitride or other dielectrics). Using an NMOS transistor as example, there are source region and drain region which are formed by an lon-implantation plus thermal annealing technique to implant high concentration n-type dopants into a p-type substrate (or a p-well) which thus results in two separated n+/p junction areas. Furthermore, to lessen impact ionization and hot carrier injection prior to highly doped n+/p junction, it is common to form a lightly doped-drain (LDD) region before the highly doped n+ source/drain region by lon-implantation plus thermal annealing technique, and such lon-implantation plus thermal annealing technique frequently causes the LDD regions penetrating into the portion of the 3D active regions which are underneath the gate structure. Therefore, the effective channel between the LDD regions is unavoidably shortened and results to short channel effect (SCE).

On the other hand, the advancement of manufacturing process technologies is continuing to move forward rapidly by scaling down the geometries of devices in both horizontal and vertical dimensions (such as the minimum feature size called as Lamda (A) is shrunk from 28 nm down to 5 nm or 3 nm). But many problems are introduced or getting worse due to such FinFET or tri-gate geometry scaling:
(1) As the device gate length is scaled down, its off state current (loff) is getting harder to be reduced. The leakage current path is formed within Fin structure (the dash rectangle region 16 in FIG. 1A which is a cross section), rather than only depending on the surface of the fin structure. Such leakage current path was evaluated and simulated as shown in FIG. 1B, in which the left figure (a) is the 3D FinFET structure under TCAD simulation, the middle figure (b) is the cross section view of the 3D FinFET structure along the red dot rectangle 18 in the left figure (a), and the right figure (c) is the off state current distribution. (“Impact of Current Flow Shape in Tapered (Versus Rectangular) FinFET on Threshold Voltage Variation Induced by Work-Function Variation”, IEEE TRANSACTIONS ON ELECTRON DEVICES, VOL. 61, NO. 6, June 2014).
(2) As the device dimensions are scaled down, it's getting harder to align the LDD junction edge (or Source/Drain edge) to the edge of Gate structure in a perfect position by only following the conventional self-alignment method of using gate, spacer and ion-implantation formation. In addition, the thermal annealing process for removing the ion-implantation damages must count on high temperature processing techniques such as Rapid thermal annealing method by using various energy sources or other thermal processes. One problem thus created is that a Gate-Induced Drain Leakage (GIDL) leakage which is hard to be controlled regardless the fact that it should be minimized in order to reduce leakage currents; the other problem as created is that the effective channel length is difficult to be controlled and so the short channel effect (SCE) is hardly minimized. It is difficult to adjust the relative position between the Source/Drain edge to the edge of Gate structure such that the GIDL could be reduced in a more controllable way.
(3) Since the ion-implantation to form the LDD structure (or the n+/p junction in NMOS or the p+/n junction in PMOS) works like bombardments in order to insert ions from the top of a silicon surface straight down to the substrate, it is hard to create uniform material interfaces with lower defects from the Source and Drain regions to the channel and the substrate-body regions since the dopant concentrations are non-uniformly distributed vertically from the top surface with higher doping concentrations down to the junction regions with lower doping concentrations.
(4) As the device dimension is scaled down to 7 nm, 5 nm or 3 nm, the height of the Fin structure (such as 50˜ 100 nm) is far larger than the width of the Fin structure (such as 3˜10 nm) such that the Fin structure is vulnerable or even collapsed during the subsequent processes (such as Source/Drain formation, Gate formation, etc.).

### SUMMARY OF THE DISCLOSURE

One object of the present disclosure is to provide a transistor structure, wherein the transistor structure includes a semiconductor convex structure and a gate structure with a gate conductive layer and a gate dielectric layer. Wherein a set of trenches are formed in the semiconductor convex in structure. The gate conductive layer is across over the semiconductor convex structure, and a portion of the gate conductive layer is filled in the set of trenches.

According to one embodiment of the present disclosure, a bottom surface and sidewalls of each of the set of trenches are covered by the gate dielectric layer.

According to one embodiment of the present disclosure, a bottom of the gate conductive layer outside the semiconductor convex structure is lower than that of the portion of the gate conductive layer filled in one of the set of trenches.

According to one embodiment of the present disclosure, the semiconductor convex structure comprises a plurality of vertical thin bodies, and the gate dielectric layer is disposed between the gate conductive layer and the plurality of vertical thin bodies.

According to one embodiment of the present disclosure, transistor structure further includes a source region, a drain region, a first concave and a second concave. The source region contacts with a first end of the semiconductor convex structure. The drain region contacts with a second end of the semiconductor convex structure. The first concave accommodates the source region. The second concave accommodates the drain region; wherein sidewalls of the first concave and sidewalls of the second concave are surrounded by a STI region.

According to one embodiment of the present disclosure, an edge of the source region contacts with the plurality of vertical thin bodies, and an edge of the drain region contacts with the plurality of vertical thin bodies.

According to one embodiment of the present disclosure, the source region comprises an LDD region contacting with the plurality of vertical thin bodies; a heavily doped region laterally extending from the LDD region; and a metal region being in the first concave and contacting with a sidewall of the heavily doped region.

According to one embodiment of the present disclosure, the transistor structure further includes an oxide layer, wherein the oxide layer is positioned in the first concave; the oxide layer includes a vertical portion and a lateral portion covering a bottom of the first concave; and a top surface of the vertical portion is higher than that of the lateral portion.

According to one embodiment of the present disclosure, a width of one of the vertical thin bodies is not greater than 3 nm.

According to one embodiment of the present disclosure, the set of trenches includes two trenches, and the plurality of vertical thin bodies includes three vertical thin bodies.

According to one embodiment of the present disclosure, the semiconductor convex structure includes a plurality of upward extending bodies. The set of trenches is formed in the semiconductor convex structure to separate the plurality of upward extending bodies. No STI region is between two of the plurality of upward extending bodies.

According to one embodiment of the present disclosure, a bottom of each of the set of trenches directly contacts with the first semiconductor material.

According to one embodiment of the present disclosure, the transistor structure further includes a source region, a drain region and a gate region. The source region contacts with the semiconductor convex structure; the drain region contacts with the semiconductor convex structure; and the gate region has a gate conductive layer across over the semiconductor convex structure.

According to one embodiment of the present disclosure, the source region contacts with each of the plurality of upward extending bodies, and the drain region contact with each of the plurality of upward extending bodies.

### BRIEF DESCRIPTION OF THE DRAWINGS

The above and other aspects of the disclosure will become better understood with regard to the following detailed description of the preferred but non-limiting embodiment(s). The following description is made with reference to the accompanying drawings:

FIG. 1A is a diagram illustrating a higher leakage current path formed within fin structure.

FIG. 1B is a diagram illustrating a 3D FinFET structure under Technology Computer-Aided Design (TCAD) simulation, a cross section view of the 3D FinFET structure, and an OFF state current distribution.

FIG. 2A(1) is a top view illustrating the structure after the semiconductor convex structure is formed in the semiconductor substrate 201;

FIG. 2A(2) is a cross-sectional view taken alone the cutting-line C2A1 as depicted in FIG. 2A(1); FIG. 2A(3) is a cross-sectional view taken alone the cutting-line C2A2 as depicted in FIG. 2A(1);

FIG. 2B(1) is a top view illustrating the structure after the composited spacer structure is formed on the top of the semiconductor convex structure;

FIG. 2B(2) is a cross-sectional view taken alone the cutting-line C2B1 as depicted in FIG. 2B(1); FIG. 2B(3) is a cross-sectional view taken alone the cutting-line C2B2 as depicted in FIG. 2B(1);

FIG. 2C(1) is a top view illustrating the structure after the pad dielectric layer with a through hole is formed to fill the opening, and the mask spacer is formed on the sidewalls of the through hole; FIG. 2C(2) is a cross-sectional view taken alone the cutting-line C2C1 as depicted in FIG. 2C(1); FIG. 2C(3) is a cross-sectional view taken alone the cutting-line C2C2 as depicted in FIG. 2C(1);

FIG. 2D(1) is a top view illustrating the structure after the exposed portion of the space is removed from the through hole; FIG. 2D(2) is a cross-sectional view taken alone the cutting-line C2D1 as depicted in FIG. 2D(1); FIG. 2D(3) is a cross-sectional view taken alone the cutting-line C2D2 as depicted in FIG. 2D(1);

FIG. 2E(1) is a top view illustrating the structure after the set of trenches and the vertical thin bodies 2 are defined in the semiconductor convex structure; FIG. 2E(2) is a cross-sectional view taken alone the cutting-line C2E1 as depicted in FIG. 2E(1); FIG. 2E(3) is a cross-sectional view taken alone the cutting-line C2E2 as depicted in FIG. 2E(1); FIG. 2E(4) is a cross-sectional view taken alone the cutting-line C2E3 as depicted in FIG. 2E(1);

FIG. 2F(1) is a top view illustrating the structure after the mask spacer and a portion of the composited spacer structure are removed; FIG. 2F(2) is a cross-sectional view taken alone the cutting-line C2F1 as depicted in FIG. 2F(1); FIG. 2F(3) is a cross-sectional view taken alone the cutting-line C2F2 as depicted in FIG. 2F(1);

FIG. 2G(1) is a top view illustrating the structure after the dummy gate is formed in the through hole; FIG. 2G(2) is a cross-sectional view taken alone the cutting-line C2G1 as depicted in FIG. 2G(1); FIG. 2G(3) is a cross-sectional view taken alone the cutting-line C2G2 as depicted in FIG. 2G(1);

FIG. 2H(1) is a top view illustrating the structure after the patterned pad dielectric layer and the remained portion of the composited spacer structure are then removed; FIG. 2H(2) is a cross-sectional view taken alone the cutting-line C2H1 as depicted in FIG. 2H(1); FIG. 2H(3) is a cross-sectional view taken alone the cutting-line C2H2 as depicted in FIG. 2H(1); FIG. 2H(4) is a cross-sectional view taken alone the cutting-line C2H3 as depicted in FIG. 2H(1);

FIG. 2I(1) is a top view illustrating the structure after the source trench and the drain trench in the semiconductor convex structure; FIG. 2I(2) is a cross-sectional view taken alone the cutting-line C2I1 as depicted in FIG. 2I(1); FIG. 2I(3) is a cross-sectional view taken alone the cutting-line C2I2 as depicted in FIG. 2I(1); FIG. 2I(4) is a cross-sectional view taken alone the cutting-line C2I3 as depicted in FIG. 2I(1);

FIG. 2J(1) is a top view illustrating the structure after the oxidation layer on the bottoms and sidewalls of the source trench and a drain trench 214B; FIG. 2J(2) is a cross-sectional view taken alone the cutting-line C2J1 as depicted in FIG. 2J(1); FIG. 2J(3) is a cross-sectional view taken alone the cutting-line C2J2 as depicted in FIG. 2J(1); FIG. 2J(4) is a cross-sectional view taken alone the cutting-line C2J3 as depicted in FIG. 2J(1);

FIG. 2K(1) is a top view illustrating the structure after the source region and the drain region accommodating in the concaves of the source trench and a drain trench are formed; FIG. 2K(2) is a cross-sectional view taken alone the cutting-line C2K1 as depicted in FIG. 2K(1); FIG. 2K(3) is a cross-sectional view taken alone the cutting-line C2K2 as depicted in FIG. 2K(1); FIG. 2K(4) is a cross-sectional view taken alone the cutting-line C2K3 as depicted in FIG. 2K(1);

FIG. 2L(1) is a top view illustrating the structure after the gate structure is formed; FIG. 2L(2) is a cross-sectional view taken alone the cutting-line C2L1 as depicted in FIG. 2L(1); FIG. 2L(3) is a cross-sectional view taken alone the cutting-line C2L2 as depicted in FIG. 2L(1); FIG. 2L(4) is a cross-sectional view taken alone the cutting-line C2L3 as depicted in FIG. 2L (1); FIG. 2L(5) is a cross-sectional view taken alone the cutting-line C2L3 as depicted in FIG. 2L(1) illustrating the gate structure according to another embodiment of the present disclosure;

FIG. 2M(1) is a perspective view illustrating the transistor structure;

FIG. 2M(2) is a cross-sectional view taken alone the dash rectangle region as depicted in FIG. 2M(1); and

FIG. 3 shows the TCAD simulation results of the current density comparison at ON and OFF states regarding the conventional FinFET and the transistor structure provided by the present invention.

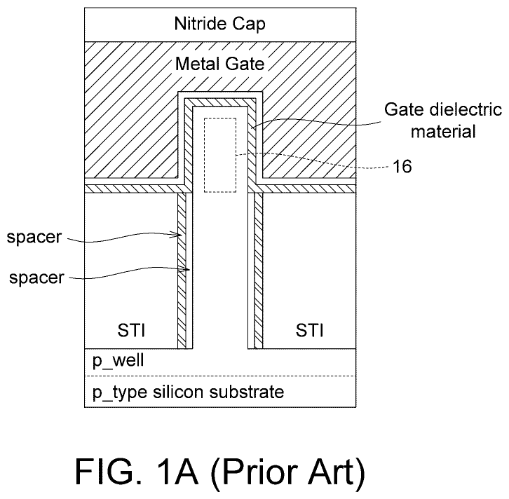

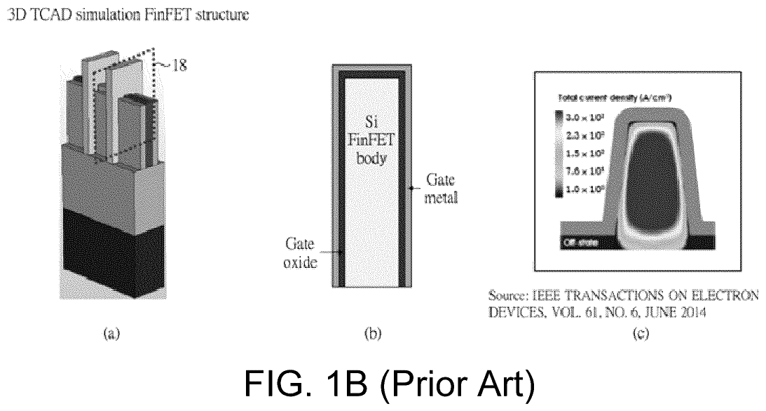

### DETAILED DESCRIPTION OF THE DISCLOSURE

The present disclosure provides a transistor structure and method for manufacturing the same to protect the fine structure of the transistor structure and to make the distance between the edge of the Source/Drain region and the edge of the Gate region controllable for reduce the GIDL and to reduce the leakage current path during the off state. Thus, a new 3D transistor structure of this invention can be a solution, e.g. of reducing loff by 10 to 100 times. The above and other aspects of the disclosure will become better understood by the following detailed description of the preferred but non-limiting embodiment(s). The following description is made with reference to the accompanying drawings:

Several embodiments of the present disclosure are disclosed below with reference to accompanying drawings. However, the structure and contents disclosed in the embodiments are for exemplary and explanatory purposes only, and the scope of protection of the present disclosure is not limited to the embodiments. It should be noted that the present disclosure does not illustrate all possible embodiments, and anyone skilled in the technology field of the disclosure will be able to make suitable modifications or changes based on the specification disclosed below to meet actual needs without breaching the spirit of the disclosure. The present disclosure is applicable to other implementations not disclosed in the specification.

### Embodiment 1

The present embodiment discloses a transistor structure 20 formed in a semiconductor substrate 201 with an original semiconductor surface, wherein the semiconductor substrate is made of a semiconductor material. Detailed steps of the manufacturing method of the transistor structure 20 are as follows:
Step S21: At least one semiconductor convex structure 201F (active region) surrounded by a shallow trench isolation (STI) region 202 is defined in a semiconductor substrate 201; wherein Step S21 includes Sub-steps S211-S214:
   Sub-step S211: A portion of the semiconductor substrate 201 are removed using a patterned pad dielectric layer 210 (including a patterned pad oxide layer 210A and a patterned pad nitride layer 210B) to defined at active region (such as, the semiconductor convex structure 201F);
   Sub-step S212: A thin thermal oxide layer 203O is formed on the sidewalls of the semiconductor convex structure 201F;
   Sub-step S213: A dielectric spacer 203N other than silicon oxide is formed on the thin thermal oxide layer 203O to form a solid wall to clamp the semiconductor convex structure 201F;
   Sub-step S214: Dielectric material is deposited and then etch back to form the STI region 202 surrounding the semiconductor convex structure 201F;
Step S22: A composited spacer structure 204 is formed on the top of the semiconductor convex structure 201F; wherein Step S22 includes Sub-steps S221-S222:
   Sub-step S221: The patterned pad dielectric layer 210 (including a patterned pad oxide layer 210A and a patterned pad nitride layer 210B) is remove to form an opening 205 for exposing the top of the semiconductor convex structure 201F and partially exposing the sidewalls of the STI region 202;
   Sub-step S222: A plurality of damascene spacer forming process are performed to form at least three spacers 204A, 204B and 204C constituting by different etching rate material and laterally stacked on the exposed portion of the sidewalls of the STI region 202 to fill the opening 205;
Step S23: A set of trenches 208A and 208B are formed in the semiconductor convex structure 201F using the composited spacer structure 204 as an etching mask;
   wherein Step S23 includes Sub-steps S231-S233: Sub-step S231: An etching back process is performed to remove a portion of the composited damascene spacer structure 204 from the opening 205 and to expose portions of the sidewalls of the STI region 202;
   Sub-step S232: Another pad dielectric layer 220 (including a patterned pad oxide layer 220A and a patterned pad nitride layer 220B) is formed on the remained portion of the composited spacer structure 204;
   Sub-step S233: The pad dielectric layer 220 is patterned to define a through hole 206 passing through the pad dielectric layer 220 to expose a portion of the composited spacer structure 204;
   Sub-step S234: A mask spacer 207 is formed on the sidewalls for define the through hole 206 for exposed at least two spacers (e.g., the spacer 204B and 204B and 204C) of the composited spacer structure 204;
   Sub-step S235: A plurality of etching process using the patterned pad dielectric layer 220 and the mask spacer 207 as an etching mask are performed to remove portions of the composited spacer structure 204 (the spacer 204B) and the semiconductor convex structure 201F from the through hole 206 to form the set of trenches 208A and 208B in the semiconductor convex structure 201F, so as to define a plurality of vertical thin bodies 201B1, 201B2 and 201B3 in the semiconductor convex structure 201F;
Step S24: A dummy gate 209 is formed in the through hole 206; wherein Step S24 includes Sub-steps S241-S244:
   Sub-step S241: The set of trenches 208A and 208B are fully filled by sacrificial material 211;
   Sub-step S242: The mask spacer 207, the portion of the composited spacer structure 204 not covered by the patterned pad dielectric layer 220 and portion of STI region 202 are removed to expose portion of the semiconductor convex structure 201F;
   Sub-step S243: A polysilicon spacer 209S is formed on the sidewalls of the through hole 206 and extending downward to the exposed portion of the semiconductor convex structure 201F;
   Sub-step S244: A dummy electrode 209E is formed to cover the sacrificial material 211 and fill the through hole 206;
Step S25: A source region 212S contacting with a first end of the semiconductor convex structure 201F and a drain region 212D contacting with a second end of the semiconductor convex structure 201F are formed; wherein Step S25 includes Sub-steps S251-S257: Sub-step S251: A low-k spacer 213 is formed to replace the polysilicon spacer 209S;
   Sub-step S252: The patterned pad dielectric layer 220 and the remained portion of the composited spacer structure 204 are removed to expose portions of the semiconductor convex structure 201F;
   Sub-step S253: The exposed portions of the semiconductor convex structure 201F are removed to form a source trench 214A and a drain trench 214B in the semiconductor convex structure 201F;
   Sub-step S254: Another thermal oxidation process is performed to form an oxidation layer 215 on the bottoms and sidewalls of the source trench 214A and the drain trench 214B;
   Sub-step S255: The portion of the oxidation layer 215 formed on the sidewalls of the source trench 214A and the drain trench 214B are removed to expose portions of the semiconductor convex structure 201F beneath the dummy electrode semiconductor convex structure 201F beneath the dummy electrode 209E;
   Sub-step S257: The source trench 214A and the drain trench 214B are filled with conductive material 212M to form the source region 212S and the drain region 212D; and
Step S26: A gate structure 217 is formed across over the semiconductor convex structure 201F; wherein Step S26 includes Sub-steps S261-S263:
   Sub-step S261: The dummy electrode 209E and the sacrificial material 211 are removed;
   Sub-step S262: A high-k dielectric layer 217D is formed to cover the sidewalls of the vertical thin bodies 201B1, 201B2 and 201B3;
   Sub-step S263: A gate conductive layer 217E is formed across over the semiconductor convex structure 201F and fill in the set of trenches 208A and 208B.

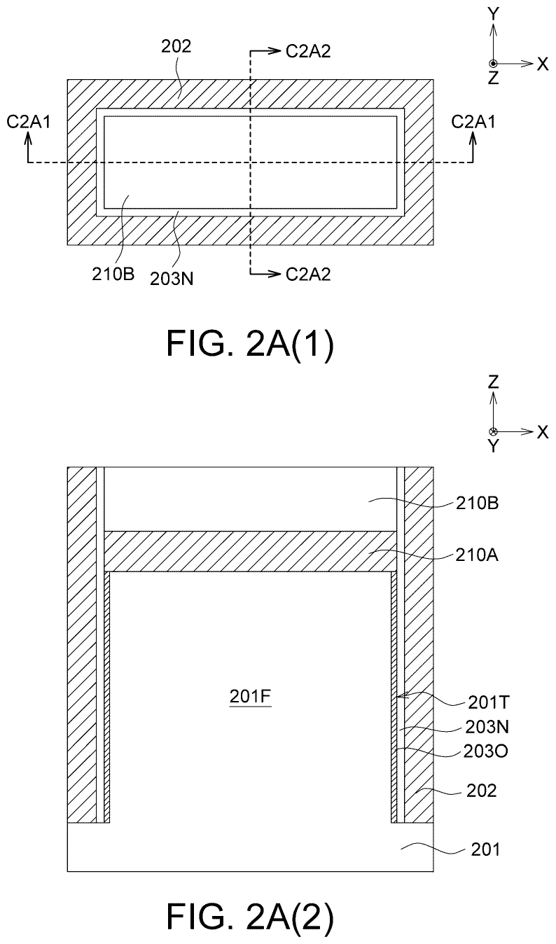

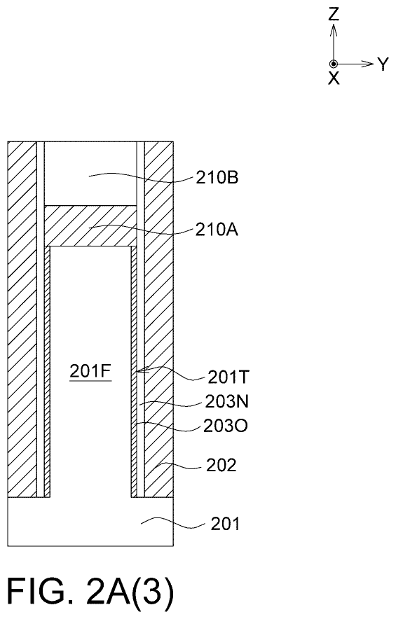

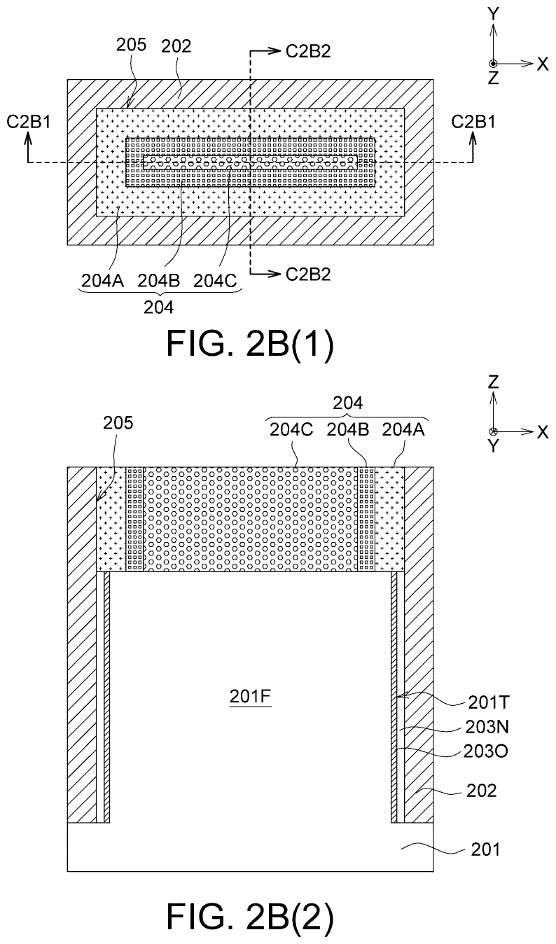

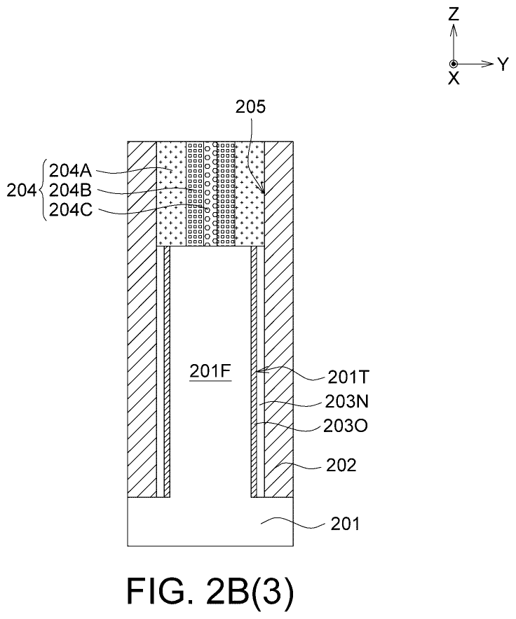

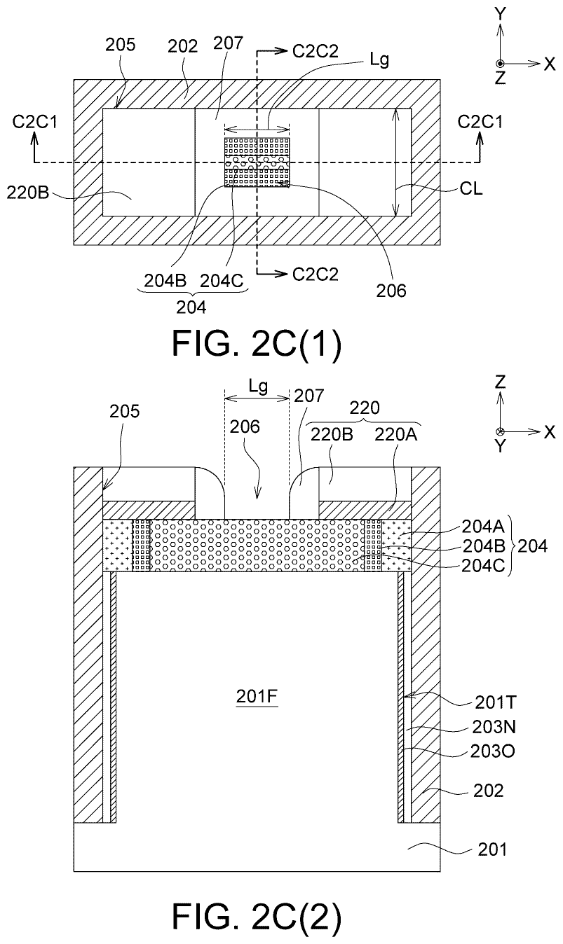

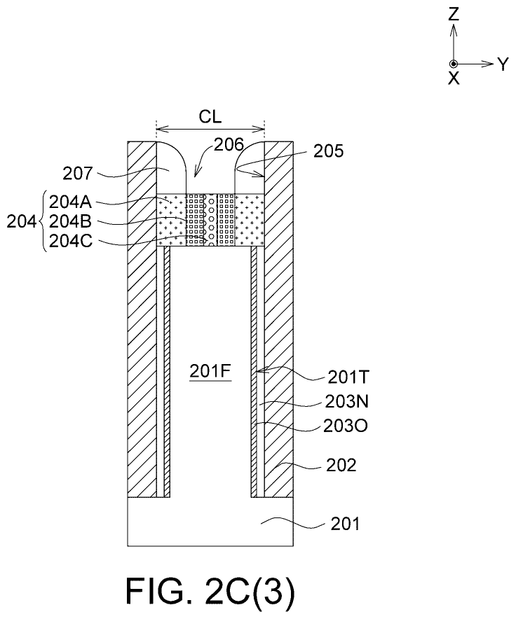

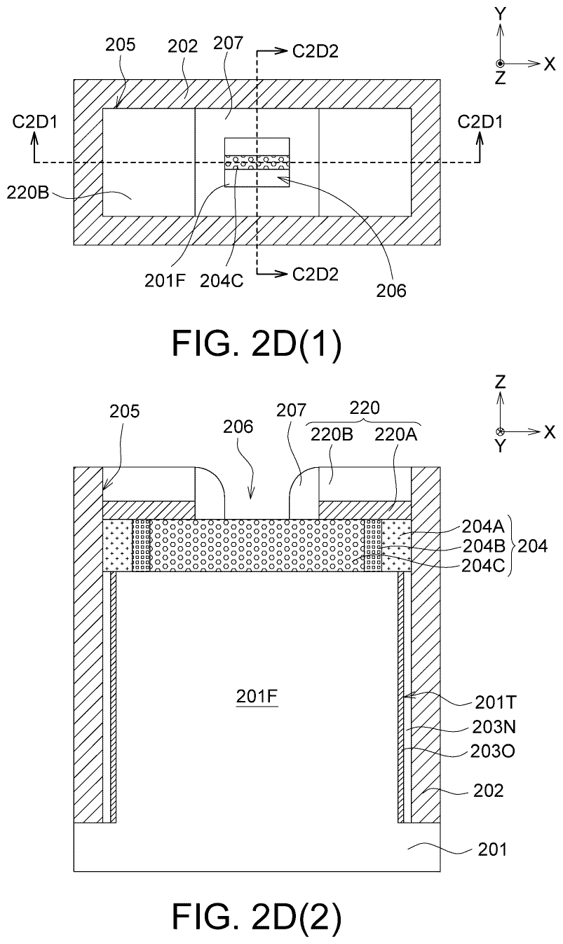

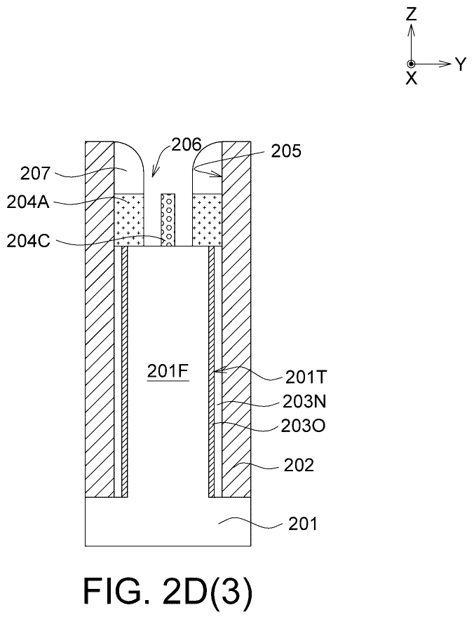

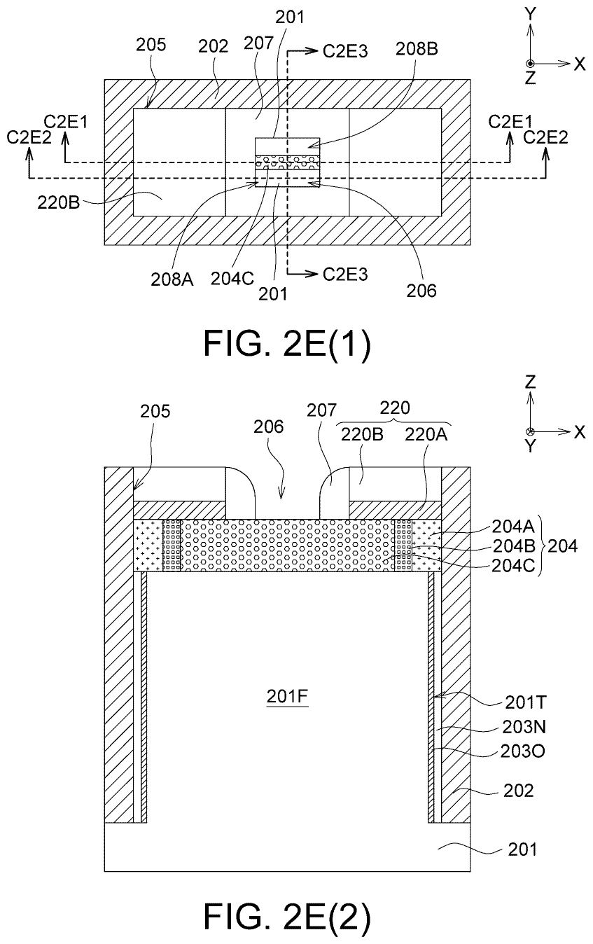

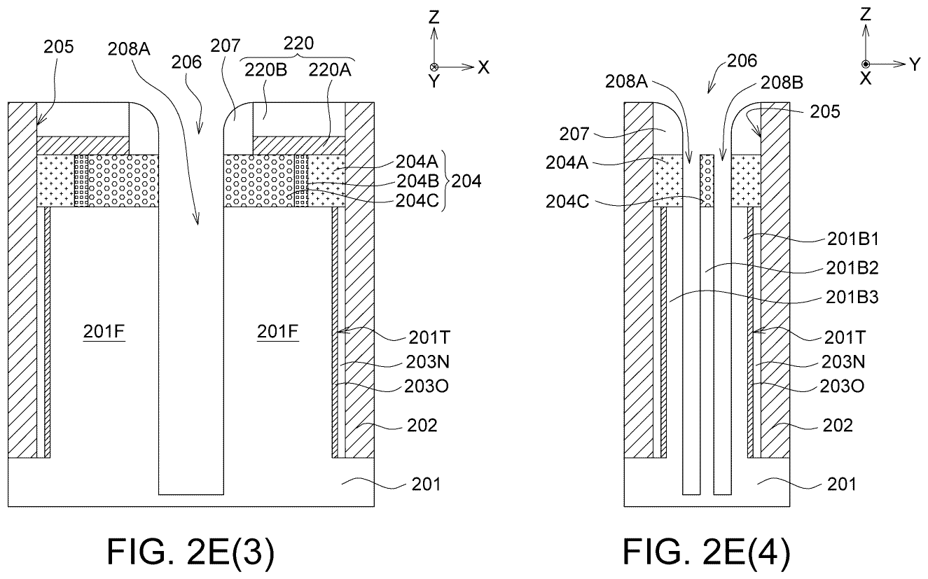

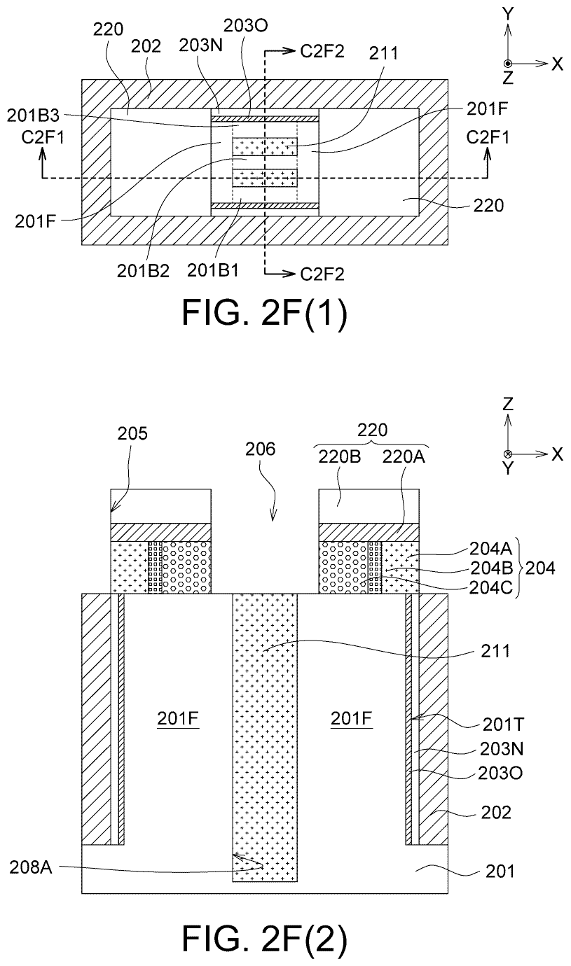

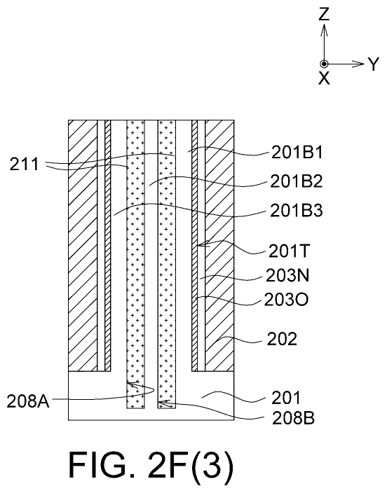

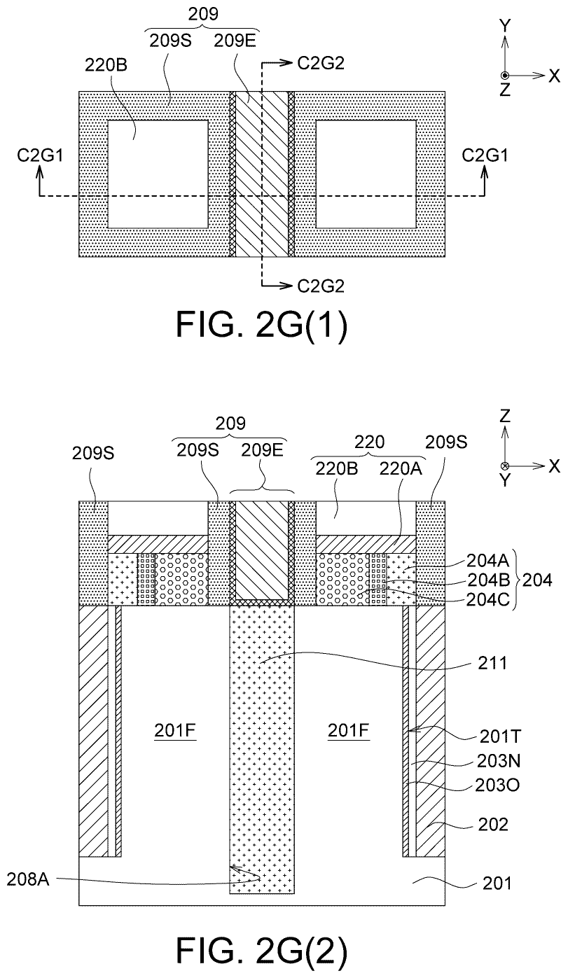

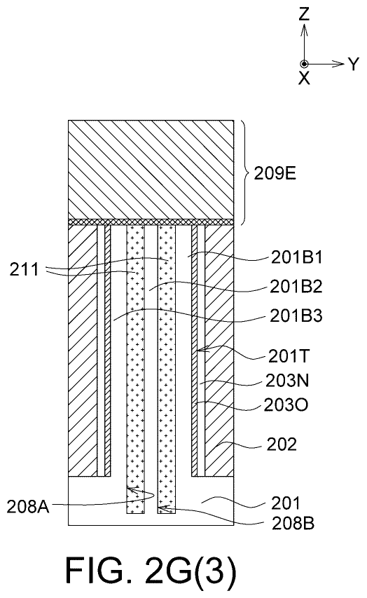

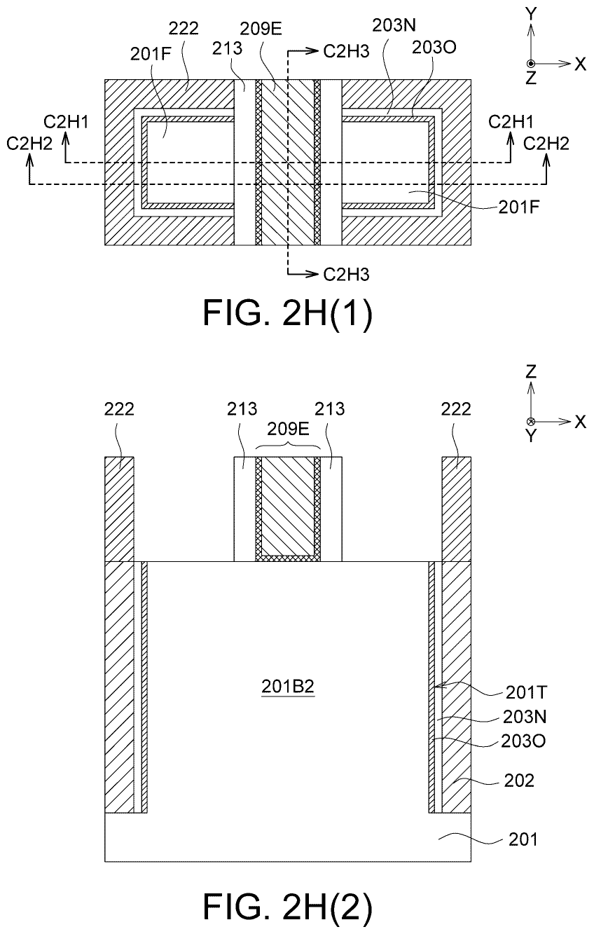

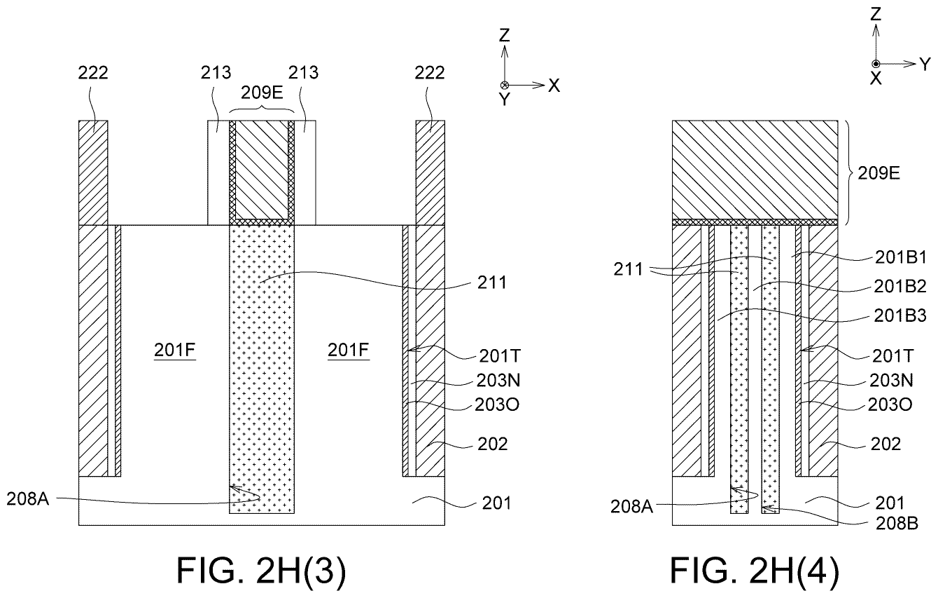

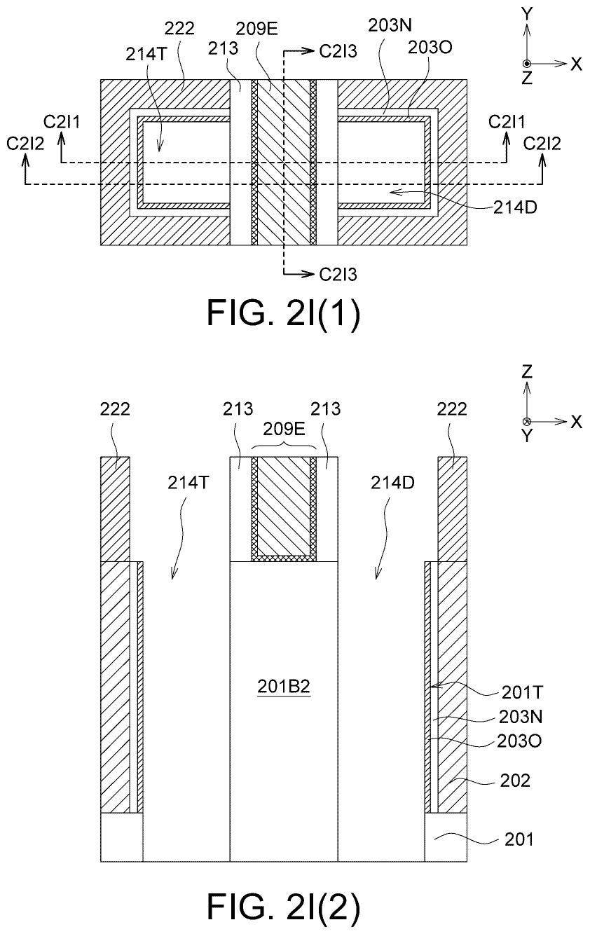

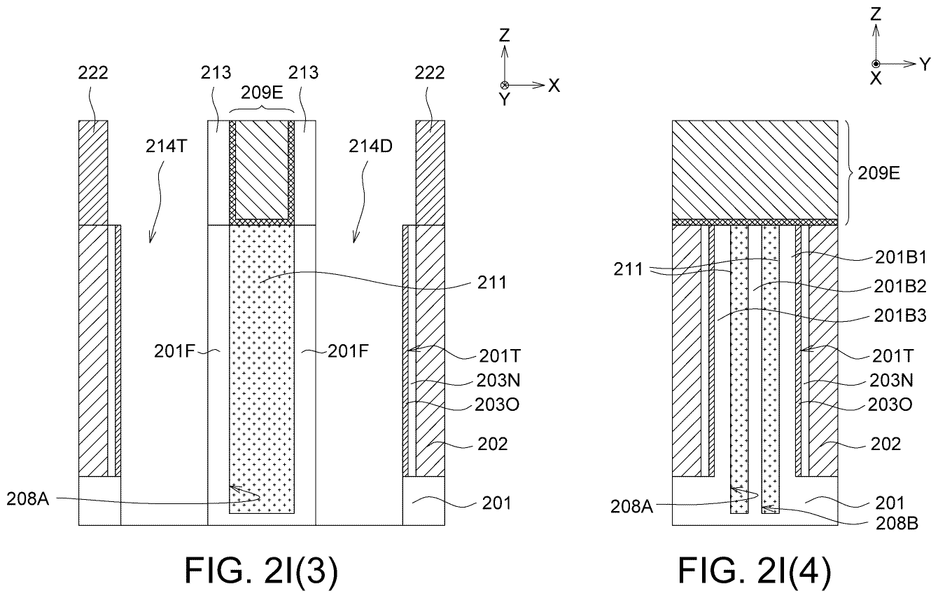

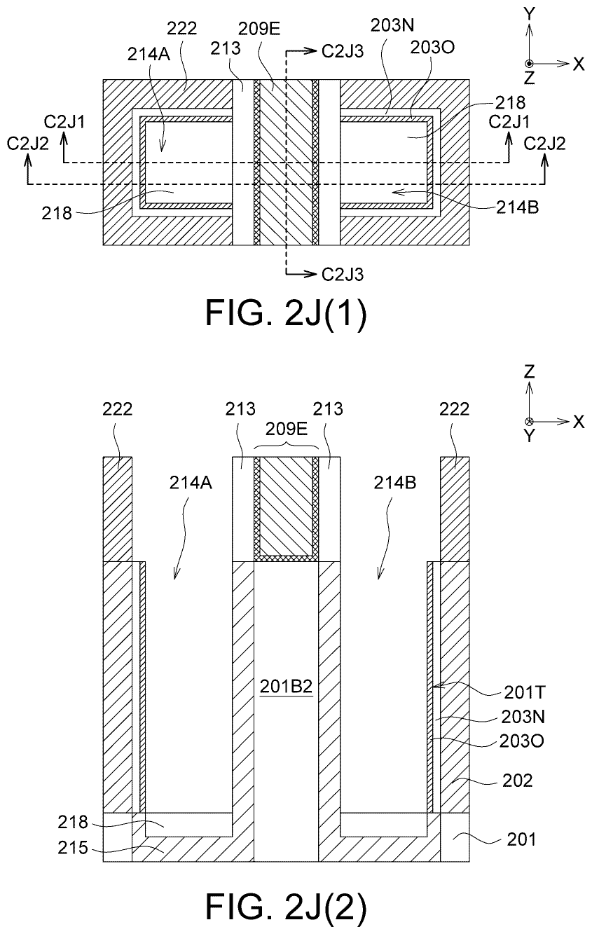

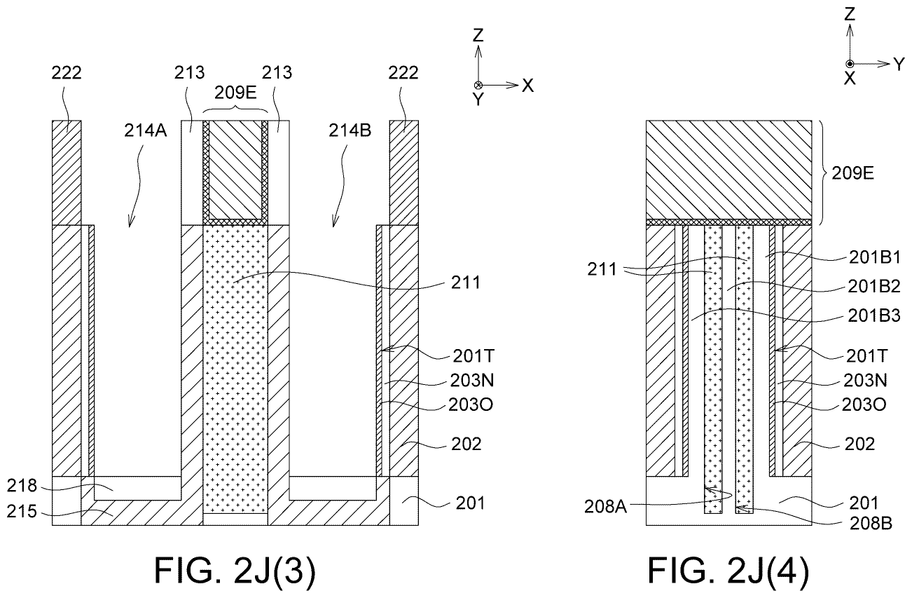

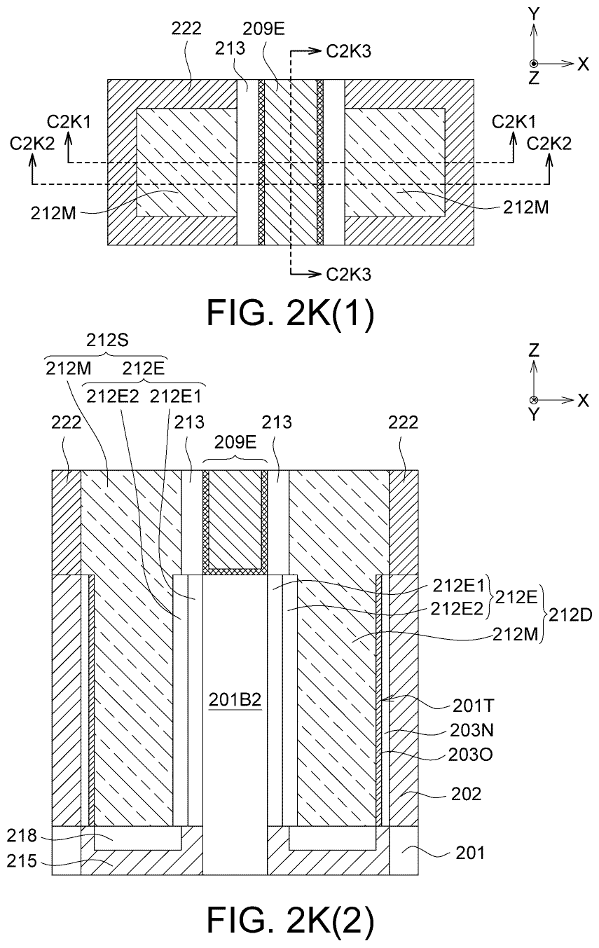

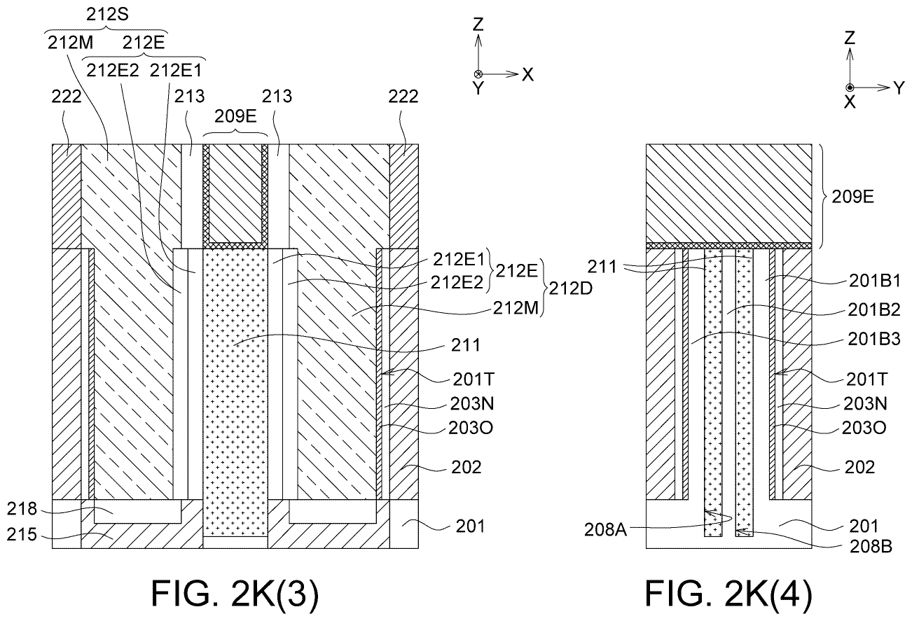

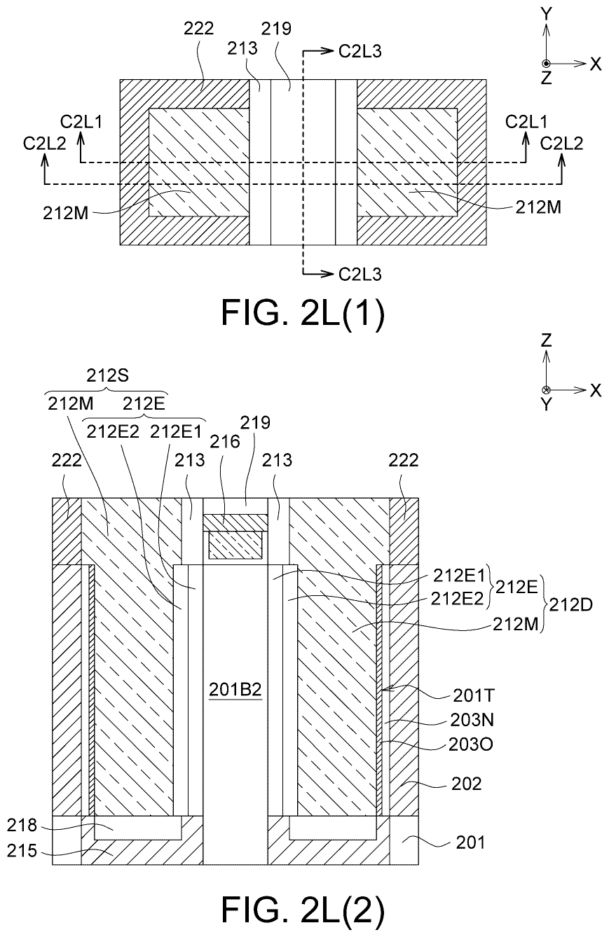

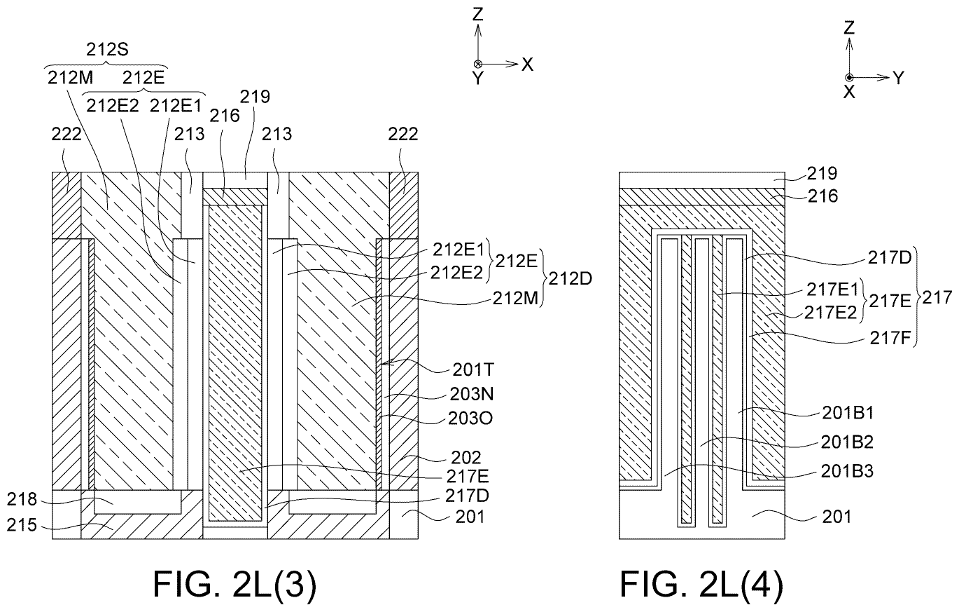

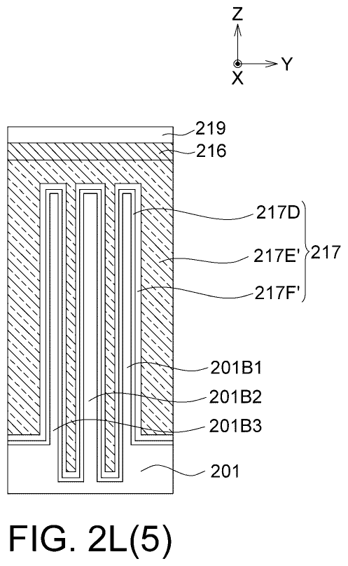

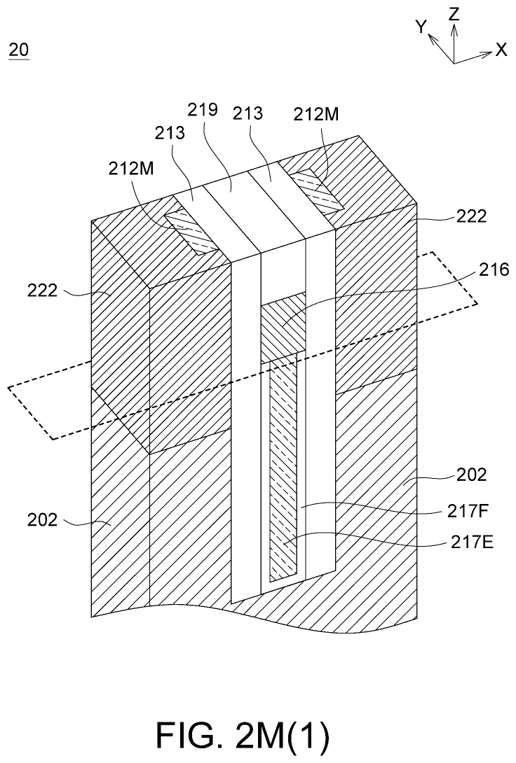

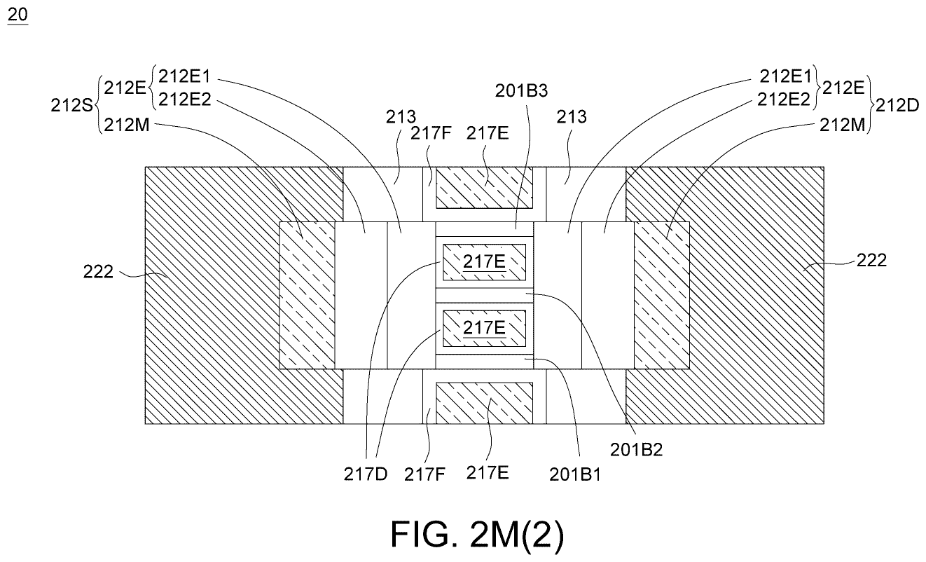

Referring to Step S21: At least one semiconductor convex structure 201F (active region) surrounded by a STI region 202 is defined in a semiconductor substrate 201. FIG. 2A(1) is a top view illustrating the structure after the semiconductor convex structure 201F is formed in the semiconductor substrate 201; FIG. 2A(2) is a cross-sectional view taken alone the cutting-line C2A1 as depicted in FIG. 2A(1); and FIG. 2A(3) is a cross-sectional view taken alone the cutting-line C2A2 as depicted in FIG. 2A(1).

The forming of the semiconductor convex structure 201F includes Sub-steps S211-S214 as follows: Firstly, an etching process using a patterned pad dielectric layer 210 (including a patterned pad oxide layer 210A and a patterned pad nitride layer 210B) as an etching mask is performed to remove parts of silicon material of a semiconductor substrate 201 to create trenches 201T and define at least fin structures serving as the semiconductor convex structure 201F in the semiconductor substrate 201 (as to Sub-step S211). In some embodiments, the semiconductor convex structure 201F has a long about 40-60 nm (such as 52 nm), a width about 18-30 nm (such as, 20.5 nm) and a height about 40-60 nm (such as 46 nm).

Next, a thin thermal oxide layer 203O is formed on the sidewalls of the semiconductor convex structure 201 (as to Sub-step S212). In some embodiments of the present disclosure, the thermal oxide layer 203O is formed by a thermal oxidation process. A dielectric spacer 203N other than silicon oxide is then formed on the thin thermal oxide layer 203O to form a solid wall to clamp the semiconductor convex structure 201F (as to Sub-step S213).

In some embodiments of the present disclosure, the dielectric spacer 203N may be a silicon nitride spacer formed by steps of depositing silicon nitride on the semiconductor substrate 201 to form a silicon nitride film covering the top and sidewalls of the semiconductor convex structure 201F; and then etching back the silicon nitride film to remain the portion of the silicon nitride film covering on the thermal oxide layer 203O. In the present embodiment, the thermal oxide layer 203O has a thickness about 1-2 nm (such as 1 or 1.5 nm), and the dielectric spacer 203N (which is made of silicon nitride) has a thickness about 2-3 nm. The solid clamping wall of the dielectric spacer 203N could be a single layer or other composite layers to protect the narrow semiconductor convex structure 201F from collapse during the subsequent processes of forming the source/drain region 212S/212D and the gate structure 217.

Then, the STI region 202 surrounding the semiconductor convex structure 201F is formed (as to Sub-step S214). In some embodiments of the present disclosure, a dietetic material (such as, silicon oxide) is deposited to fully fill the trenches 201T and then etched back, such that the dietetic material remained in the trenches 201T can serve as the STI region 202 surrounding the semiconductor convex structure 201F.

Referring to Step S22: A composited spacer structure 204 is formed on the top of the semiconductor convex structure 201F. FIG. 2B(1) is a top view illustrating the structure after the composited spacer structure 204 is formed on the top of the semiconductor convex structure 201F; FIG. 2B(2) is a cross-sectional view taken alone the cutting-line C2B1 as depicted in FIG. 2B(1); and FIG. 2B(3) is a cross-sectional view taken alone the cutting-line C2B2 as depicted in FIG. 2B(1).

The forming of the composited spacer structure 204 includes Sub-steps S221-S222 as follows: Firstly, the patterned pad dielectric layer 210 (including a patterned pad oxide layer 210A and a patterned pad nitride layer 210B) is remove to form an opening 205 for exposing the top of the semiconductor convex structure 201F and partially exposing the sidewalls of the STI region 202 (as to Sub-step S221).

In some embodiments of the present disclosure, after the pad dielectric layer 210 is removed, an optional STI etching back process may be performed to reduce the height of the exposed portion of the sidewalls of the STI region 202. In the present embodiment, since the patterned pad dielectric layer 210 has a thickness about 28 nm, thus the exposed portion of the sidewalls of the STI region 202 has an originally height about 28 nm, after the pad dielectric layer 210 is removed; and the height can be then reduced to 14-20 nm by the STI etching back process.

Next, a plurality of damascene spacer forming process are performed to form at least three spacers 204A, 204B and 204C constituting by different material and laterally stacked on the exposed portion of the sidewalls of the STI region 202 to fill the opening 205 (as to Sub-step S222). Firstly, a first dielectric material is deposited covering the STI region 202, the sidewalls of the opening 205 and the exposed top of the semiconductor convex structure 201F; and an etching back process is performed to remove the portions of the first dielectric material covering the STI region 202 and the exposed top of the semiconductor convex structure 201F. Wherein the portion of the first dielectric material remained on the exposed portion of the sidewalls of the STI region 202 can serve as the spacer 204A. In the present embodiment, the first material may include organosilicate glass (SiCOH).

Similarly, a second dielectric material different from the first one is then deposited and etched back to remain a portion of the second dielectric material laterally stacked on the spacer 204A in the opening 205 serving as the spacer 204B. In the present embodiment, the second dielectric material for forming the spacer 204B may include silicon nitride (Si₃N₄). Thereafter, more spacers made of by dielectric material different from the previous spacer are sequentially formed and laterally stacked on the previous spacer in the opening 205 by the same way until the opening is filled.

For example, in the present embodiment, the spacer 204C made of carbon- and nitride-doped silicon oxide (SiCON) is then formed and laterally stacked on the spacer 204B to full fill the opening 205. Such that, the three spacers 204A, 204B and 204C together form the composited spacer structure 204, wherein the three spacers 204A, 204B and 204C are arranged concentrically around the central axis of the opening 205. The three spacers 204A, 204B and 204C respectively have a lateral thickness of 5 nm, 7 nm and 2.5 nm (but in some other embodiments, these lateral thicknesses are not limited to this regards).

Referring to Step S23: A set of trenches 208A and 208B are formed in the semiconductor convex structure 201F using the composited spacer structure 204 as an etching mask; wherein the forming the set of trenches 208A and 208B includes Sub-steps S231-S233 as follows: Firstly, an etching back process is performed to remove a portion of the composited spacer structure 204 from the opening 205 and to expose top portions of the sidewalls of the STI region 202 again (as to Sub-steps S231).

Next, another pad dielectric layer 220 (including a patterned pad oxide layer 220A and a patterned pad nitride layer 220B) is formed on the remained portion of the composited spacer structure 204 (as to Sub-steps S232) to fill the opening 205. And an etching process is then performed to pattern the pad dielectric layer 220 and form a through hole 206 passing through the pad dielectric layer 220 to expose a portion of the composited spacer structure 204 (as to Sub-steps S233); and a mask spacer 207 is next formed on the sidewalls for define the through hole 206 for exposed at least two spacers of the composited spacer structure 204 (as to Sub-steps S234).

FIG. 2C(1) is a top view illustrating the structure after the pad dielectric layer 220 with the through hole 206 is formed to fill the opening 205 and the mask spacer 207 is formed on the sidewalls of the through hole 206; FIG. 2C(2) is a cross-sectional view taken alone the cutting-line C2C1 as depicted in FIG. 2C(1); and FIG. 2C(3) is a cross-sectional view taken alone the cutting-line C2C2 as depicted in FIG. 2C(1).

In the present embodiment, the through hole 206 and the mask spacer 207 are used to define the channel length Lg of the transistor structure 20. The through hole 206 has a length CL about 26.5 nm and a width about 14-20 nm. The mask spacer 207 formed on the sidewalls of the through hole 206 can be used to further narrow (scale down) the through hole 206 and to define channel length Lg of the transistor structure 20 about 10-15 nm. The mask spacer 207 may be made by dielectric material including SiCOH which is the same that for constituting the spacer 204A. Since the potion of the spacer 204A exposed from the through hole 206 is covered by the mask spacer 207 formed on the sidewalls of the through hole 206, thus merely the spacers 204B and 204C of the composited spacer structure 204 can be exposed from through hole 206.

Subsequently, a plurality of etching process using the patterned pad dielectric layer 220 and the mask spacer 207 as an etching mask are performed to remove portions of the composited spacer structure 204 (the spacer 204B) and the semiconductor convex structure 201F from the through hole 206 to form the set of trenches 208A and 208B in the semiconductor convex structure 201F, so as to define a plurality of vertical thin bodies 201B1, 201B2 and 201B3 in the semiconductor convex structure 201F (as to Sub-steps S235).

For example, in the present embodiment, an etching process using an etchant with a greater rate for removing Si₃N₄ than for removing SiCON can be firstly performed to remove the portion of the space 204B of the composited spacer structure 204 exposed from the through hole 206. Such that, a portion of the semiconductor convex structure 201F can be exposed from the through hole 206. FIG. 2D(1) is a top view illustrating the structure after the exposed portion of the space 204B is removed from the through hole 206; FIG. 2D(2) is a cross-sectional view taken alone the cutting-line C2D1 as depicted in FIG. 2D(1); and FIG. 2D(3) is a cross-sectional view taken alone the cutting-line C2D2 as depicted in FIG. 2D(1).

Next, another etching process using the mask spacer 207 and the remaining composited spacer structure 204 as the etching mask is performed to remove portions of the semiconductor convex structure 201F to form a plurality of trenches 208A and 208B in the semiconductor convex structure 201F. Such that, a plurality of vertical poles can be defined in the semiconductor convex structure 201F by the plurality of trenches 208A and 208B serving as the vertical thin bodies 201B1, 201B2 and 201B3.

FIG. 2E(1) is a top view illustrating the structure after the set of trenches 208A and 208B and the vertical thin bodies 201B1, 201B2 and 201B3 are defined in the semiconductor convex structure 201F; FIG. 2E(2) is a cross-sectional view taken alone the cutting-line C2E1 as depicted in FIG. 2E(1); FIG. 2E(3) is a cross-sectional view taken alone the cutting-line C2E2 as depicted in FIG. 2E(1); and FIG. 2E(4) is a cross-sectional view taken alone the cutting-line C2E3 as depicted in FIG. 2E(1).

In some embodiments of the present disclosure, the trenches 208A and 208B are etched through the semiconductor convex structure 201F and down to the semiconductor substrate 201. Of note that the three silicon vertical thin bodies 201B1, 201B2 and 201B3, at this stage, are still connected together by the remaining silicon body of the semiconductor convex structure 201F (as shown in FIG. FIG. 2E(4)) to prevent the three silicon vertical thin bodies 201B1, 201B2 and 201B3 from collapse. In some embodiment, the lateral thickness/width of each of the vertical thin bodies 201B1, 201B2 and 201B3 is around 2-5 nm, such as 2.5 or 3 nm. By adjusting the thickness of different layer of composited spacer structure 204, each thin bodies 201B1, 201B2 and 201B3 could have the same or substantially the same lateral thickness/width. Moreover, there is no STI region between the vertical thin bodies 201B1, 201B2 and 201B3.

Referring to Step S24: A dummy gate 209 is formed in the through hole 206; wherein the forming of the dummy gate 209 includes Sub-steps as follows: Firstly, the set of trenches 208A and 208B are fully filled by sacrificial material 211 (as s sub-steps S241). In some embodiments of the present disclosure, the sacrificial material 211 may include SiCOH or spin on glass (SOG). In the present embodiment, SOG material is refilled in both trenches 208A and 208B to form SOG column poles to strength the three silicon vertical thin bodies 201B1, 201B2 and 201B3.

Next, an etching process is firstly performed to remove the mask spacer 207 (made of SiCOH), and then another etching process is performed to remove the portion of the composited spacer structure 204 (e.g., the spacer 204C made of SiCON) not covered by the patterned pad dielectric layer 220, such that the sacrificial material 211 and a portion of the semiconductor convex structure 201F can be exposed from the through hole 206 (as to Sub-steps S242).

FIG. 2F(1) is a top view illustrating the structure after the mask spacer 207 and the portion of the composited spacer structure 204 are removed; FIG. 2F(2) is a cross-sectional view taken alone the cutting-line C2F1 as depicted in FIG. 2F(1); and FIG. 2F(3) is a cross-sectional view taken alone the cutting-line C2F2 as depicted in FIG. 2F(1). In the embodiment, the top portion of the STI region 202 can be etched back during removing the portion of the composited spacer structure 204. Such that, the spacer 204A and the sidewalls of the pad dielectric layer 220 (including a patterned pad oxide layer 220A and a patterned pad nitride layer 220B) can be exposed.

Thereafter, a polysilicon spacer 209S is formed on the sidewalls of the through hole 206 and extending downward to the exposed portion of the semiconductor convex structure 201F (as to Sub-step S243). A dummy electrode 209E is then formed to cover the sacrificial material 211 and fill the through hole 206 (as to Sub-step S244). The portion of the polysilicon spacer 209S and the dummy electrode 209E filling the through hole 206 are together to form the dummy gate 209. In some embodiments of the present disclosure, the dummy electrode 209E includes a TiN barrier layer and a tungsten (W) body.

FIG. 2G(1) is a top view illustrating the structure after the dummy gate 209 is formed in the through hole 206; FIG. 2G(2) is a cross-sectional view taken alone the cutting-line C2G1 as depicted in FIG. 2G(1); and FIG. 2G(3) is a cross-sectional view taken alone the cutting-line C2G2 as depicted in FIG. 2G(1). In the present embodiment, the polysilicon spacer 209S is also formed on the etched back STI region 202 to cover the exposed spacer 204A and the sidewalls of the pad dielectric layer 220 (including a patterned pad oxide layer 220A and a patterned pad nitride layer 220B).

Refer to Step S25: A source region 212S contacting with a first end of the semiconductor convex structure 201F and a drain region 212D contacting with a second end of the semiconductor convex structure 201F are formed; wherein the forming of the source region 212S and drain region 212D includes Sub-steps S251-S254 as follows:

Firstly, a low-k spacer 213 is formed to replace the polysilicon spacer 209S (as to Sub-step S251). In some embodiments of the present disclosure, an anisotropic etching process using a patterned photoresist layer (not shown) is performed to merely remove the portion of the polysilicon spacer 209S formed on the sidewalls of the through hole 206 to form a concave region in the through hole 206 for exposing a portion of the semiconductor convex structure 201F. Next, a low-k material (a dielectric material with a dielectric constant value (k) less than that of SiO₂) is deposited to fill the concave region and then etched back to form the low-k spacer 213.

Subsequently, the patterned pad dielectric layer 220 and the remained portion of the composited spacer structure 204 are removed to expose portions of the semiconductor convex structure 201F (as to Sub-step S252). In the present embodiment, a plurality of etching processes are performed to respectively remove the patterned pad dielectric layer 220 and the remained portion of the composited spacer structure 204 with different materials. FIG. 2H(1) is a top view illustrating the structure after the patterned pad dielectric layer 220 and the remained portion of the composited spacer structure 204 are then removed; FIG. 2H(2) is a cross-sectional view taken alone the cutting-line C2H1 as depicted in FIG. 2H(1); FIG. 2H(3) is a cross-sectional view taken alone the cutting-line C2H2 as depicted in FIG. 2H(1); and FIG. 2H(4) is a cross-sectional view taken alone the cutting-line C2H3 as depicted in FIG. 2H(1).

In some embodiments of the present disclosure, prior to remove patterned pad dielectric layer 220 and the remained portion of the composited spacer structure 204, the portion of the polysilicon spacer 209S formed on the etched back STI region 202 can be replaced with a low-K material spacer 222. For example, in the present embodiment, the portion of the polysilicon spacer 209S formed on the etched back STI region 202 can be firstly etched back to exposed the top of the STI region 202; SOG is then deposited, and a following planarization (such as, a chemical mechanical polishing (CMP)) process is performed to form the low-K material spacer 222 extending from the top of the etched back STI region 202 and surrounding the semiconductor convex structure 201F.

Thereafter, the exposed portions of the semiconductor convex structure 201F are removed to form a source trench 214A and a drain trench 214B in the semiconductor convex structure 201F (as to Sub-step S253). FIG. 2I(1) is a top view illustrating the structure after the source trench 214A and the drain trench 214B in the semiconductor convex structure 201F; FIG. 2I(2) is a cross-sectional view taken alone the cutting-line C2I1 as depicted in FIG. 2I(1);

FIG. 2I(3) is a cross-sectional view taken alone the cutting-line C2I2 as depicted in FIG. 2I(1); and FIG. 2I(4) is a cross-sectional view taken alone the cutting-line C2I3 as depicted in FIG. 2I(1). In some embodiment of the present disclosure, the exposed portions of the semiconductor convex structure 201F are etched down to around 70 nm to form the source trench 214A and the drain trench 214B in the semiconductor convex structure 201F.

Another thermal oxidation process is then performed to form an oxidation layer 215 on the bottoms and sidewalls of the source trench 214A and the drain trench 214B (as to Sub-step S254). FIG. 2J(1) is a top view illustrating the structure after the oxidation layer 215 on the bottoms and sidewalls of the source trench 214A and a drain trench 214B; FIG. 2J(2) is a cross-sectional view taken alone the cutting-line C2J1 as depicted in FIG. 2J(1); FIG. 2J(3) is a cross-sectional view taken alone the cutting-line C2J2 as depicted in FIG. 2J(1); and FIG. 2J(4) is a cross-sectional view taken alone the cutting-line C2J3 as depicted in FIG. 2J(1).

In the present embodiment, the oxidation layer 215 may include a vertical portion formed on the sidewalls of the source trench 214A and the drain trench 214B and a horizontal portion formed on the bottom of the source trench 214A and the drain trench 214B. In some embodiment of the present disclosure, a bottom nitride layer 218 can optionally formed on the horizontal portion of the oxidation layer 215 by performing a nitride depositing process followed by an etching back process.

After the vertical portion of the oxidation layer 215 formed on the sidewalls of the source trench 214A and a drain trench 214B are removed to expose vertical sidewalls of the semiconductor convex structure 201F beneath the dummy electrode 209E (as to Sub-step S255), an epitaxy growth process is performed based on the vertical sidewalls of the semiconductor convex structure 201F beneath the dummy electrode 209E to form epitaxy regions 212E(as to Sub-step S256). In some embodiments of the present, the epitaxy regions 212E are formed by a selective epitaxy growth process. In the present embodiment, each of the epitaxy regions 212E includes a lightly doped drain (LDD) sub-regions 212E1 and a highly doped sub-region 212E2.

Subsequently, the concaves of the source trench 214A and the drain trench 214B are filled with conductive material 212M contacting to the epitaxy regions 212E to form the source region 212S and the drain region 212D (as to Sub-step S257). FIG. 2K(1) is a top view illustrating the structure after the source region 212S and the drain region 212D accommodating in the concaves of the source trench 214A and a drain trench 214B are formed; FIG. 2K(2) is a cross-sectional view taken alone the cutting-line C2K1 as depicted in FIG. 2K(1); FIG. 2K(3) is a cross-sectional view taken alone the cutting-line C2K2 as depicted in FIG. 2K(1); and FIG. 2K(4) is a cross-sectional view taken alone the cutting-line C2K3 as depicted in FIG. 2K(1). Since a top surface of the composite STI region comprising the low-K material spacer 222 and the etched back STI region 202 is higher than the original semiconductor surface of the semiconductor convex structure 201F (or leveled up with the top of the low-k spacer 213), the conductive material 212M will be self-aligned with the epitaxy regions 212E, and contacts with the top and most lateral sidewalls of the epitaxy regions 212E to form metal-semiconductor junction in the Source/Drain region and reduce the contact resistance.

In the present embodiment TiN/W metal deposition process followed by an etching back process are performed to fill the source trench 214A and the drain trench 214B. The conductive material 212M (TiN/W metal) and the epitaxy regions 212E accommodating in the concaves of the source trench 214A together form the source region 212S; and the conductive material 212M (TiN/W metal) and the epitaxy regions 212E accommodating in the concaves of the drain trench 214B together form the source region 212S.

Refer to Step S26: A gate structure 217 is formed across over the semiconductor convex structure 201F. The forming of the gate structure 217 includes sub-steps S261-S263 as follows: Firstly, the dummy electrode 209E and the sacrificial material 211 are removed (as to sub-steps S261), In the present embodiment a plurality of etching processes are performed to respectively remove the dummy electrode 209E and the sacrificial material 211 fully filled in the set of trenches 208A and 208B.

Next, a high-k dielectric layer 217D is formed to cover the sidewalls of the vertical thin bodies 201B1, 201B2 and 201B3 (as to sub-steps S262). In the present embodiment, a portion of the high-k dielectric layer 217D is firstly formed to cover the sidewalls of the vertical thin bodies 201B1, 201B2 and 201B3 exposed from the set of trenches 208A and 208B. After the portions of the STI region 202, the thin thermal oxide layer 203O and the dielectric spacer 203N covering on the other sidewalls of the vertical thin bodies 201B1, 201B2 and 201B3 are etched back; the other portion of the high-k dielectric layer 217D can be formed on the exposed sidewalls of the vertical thin bodies 201B1, 201B2 and 201B3.

In addition, prior to forming the high-k dielectric layer 217D, the vertical thin bodies 201B1, 201B2 and 201B3 can be optionally thin down by a thermal trimming process to have equal body width for 201B1, 201B2 and 201B3. In the present embodiment, the thickness of each of the vertical thin bodies 201B1, 201B2 and 201B3 can be thin down to 1.5-3 nm. The distance between adjacent twos of the vertical thin bodies (such as, the distance between the vertical thin bodies 201B1 and 201B2) can be enlarged to 8 nm.

Subsequently, a gate conductive layer 217E is formed across over the semiconductor convex structure 201F and fill in the set of trenches 208A and 208B and the openings resulted by the STI region 202 etching back process (as to sub-steps S261) to form the gate structure 217. FIG. 2L(1) is a top view illustrating the structure after the gate structure 217 is formed; FIG. 2L(2) is a cross-sectional view taken alone the cutting-line C2L1 as depicted in FIG. 2L(1); FIG. 2L(3) is a cross-sectional view taken alone the cutting-line C2L2 as depicted in FIG. 2L(1); and FIG. 2L(4) is a cross-sectional view taken alone the cutting-line C2L3 as depicted in FIG. 2L(1).

In some embodiments of the present disclosure, the gate conductive layer 217E can be formed by several metal depositing processes. For example, in the present embodiment, one portion 217E1 of the gate conductive layer 217E is first formed to fill the trenches 208A and 208B, after the portion of the high-k dielectric layer 217D covering on the sidewalls of the trenches 208A and 208B is formed. The other portion 217E2 of the gate conductive layer 217E is formed to come across over the vertical thin bodies 201B1, 201B2 and 201B3, after the other portion of the high-k dielectric layer 217D not formed in the trenches 208A and 208B is formed. In addition, prior to form the portion 217E2 of the gate conductive layer 217E, a work function layer 217F may be formed to come across over the vertical thin bodies 201B1, 201B2 and 201B3.

However, the gate structure 217′ may not be limited to this regard. In another embodiment of the present disclosure, work function layer 217F′ can cover two opposite vertical sidewalls of each vertical thin bodies 201B1, 201B2 and 201B3. FIG. 2L(5) is a cross-sectional view taken alone the cutting-line C2L3 as depicted in FIG. 2L(1) illustrating the gate structure 217′ according to another embodiment of the present disclosure. In the present embodiment, the work function layer 217F′ is formed to conformally cover the high-k dielectric layer 217D that conformally cover the vertical sidewalls of each vertical thin bodies 201B1, 201B2 and 201B3; and the gate conductive layer 217E′ is formed by one metal depositing process to come across over the vertical thin bodies 201B1, 201B2 and 201B3 and full fill the trenches 208A and 208B.

After the forming the gate structure 217, a conductive metal (such as, W or the like) is deposited to form a metal pad 216 full filling the opening defined by the low-k spacer 213 and electrically contacted to the gate conductive layer 217E; and a hard mask 219 is formed on the metal pad 216, so as to complete the fabrication of the transistor structure 20. FIG. 2M(1) is a perspective view illustrating the transistor structure 20; FIG. 2M(2) is a cross-sectional view taken alone the dash rectangle region as depicted in FIG. 2M(1).

In another embodiment, a bottom of the gate conductive layer 217E outside the semiconductor convex structure is lower than that of the portion of the gate conductive layer 217E filled in one of the set of trenches 208A and 208B; or a bottom of the gate conductive layer 217E outside the semiconductor convex structure is higher than that of the portion of the gate conductive layer 217E filled in one of the set of trenches 208A and 208B.

As shown in FIGS. 2L(5) and 2M(2), there are three vertical thin bodies (vertical poles) 201B1, 201B2 and 201B3 providing current conduction for the transistor structure 20 of the present invention, and each of the vertical thin bodies 201B1, 201B2 and 201B3 includes two vertical semiconductor sidewalls (Si body surface) covered by the high-k dielectric layer 217D (made of metal-oxide or dielectric material), which could be deemed as current connection channels. Thus, the transistor structure 20 includes 6 current conduction channels in one single semiconductor convex structure 201F or fin structure, and could be named as six-channel file-effect transistor (6CFET). It is noted that there is no STI region between the vertical thin bodies (vertical poles) 201B1, 201B2 and 201B3). In other word, there are six metal-dielectric-semiconductor structures (or MOS structures) in the six-channel file-effect transistor (6CFET).

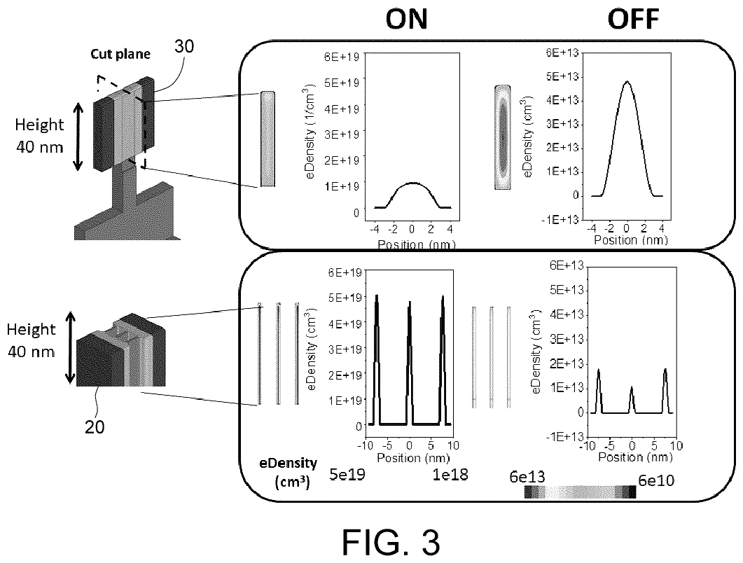

A technology computer-aided design (TCAD) simulation is performed to figure out the lon regarding the conventional FinFET transistor having two current conduction channels and the transistor structure 20 of present disclosure including 6 current conduction channels. FIG. 3 shows the TCAD simulation results of the loff regarding the conventional FinFET 30 and the transistor structure 20 provided by the present invention.

Table 1 lists the dimension parameters of the conventional FinFET 30 and the transistor structure 20 of present disclosure:

TABLE 1

| | | Thin | | | | CPP |
|---|---|---|---|---|---|---|
| Device | Fin | body | AA | Fin | Gate | (contacted |
| structure | height | width | width | pitch | length | poly |
| dimension | (nm) | (nm) | (nm) | (nm) | (nm) | pitch) |
| the | 58 nm | 6 | | 26 | 19 | 45 |
| conventional | | | | | | |
| FinFET 30 | | | | | | |
| the | 40 | 1.5 | 18.5 | 30.5 | 9 | 33 |
| transistor | | | | | | |
| structure 20 | | | | | | |
| of the | | | | | | |
| present | | | | | | |
| invention | | | | | | |

As shown in Table 1, based on the same channel length, the transistor structure 20 has smaller vertical thin body width, fine height and gate length, compared with those of the conventional FinFET 30, but has larger AA width (“VTB width”×“VTB number”+ “conductive pole width”×“conductive pole number”).

Table 2 lists the electrical parameters of the conventional FinFET 30 and the transistor structure 20 of present disclosure:

TABLE 2

| Device | Wsd | WF | Vt | SS | DIBL | Ioff | Ion | on/off |
|---|---|---|---|---|---|---|---|---|
| structure | (nm) | (eV) | (mV) | (mV/dec) | (mV/V) | (pA) | (uA) | (10⁶) |
| the | 6 nm | 4.52 | 330 | 82 | 78 | 140 | 63 | 0.4 |
| conventional | | | | | | | | |
| FinFET 30 | | | | | | | | |
| Lg = 10 nm | | | | | | | | |
| the | 24.5 | 4.22 | 330 | 73 | 31 | 46 | 186 | 4 |
| transistor | | | | | | | | |
| structure 20 | | | | | | | | |
| Lg = 10 nm | | | | | | | | |
| Body | | | | | | | | |
| width1.5 nm | | | | | | | | |

As described in Table 2, the conventional FinFET 30 has 6 nm fin width, 70 nm fin height, 1 nm thickness gate oxide, and the transistor structure 20 of present disclosure has three Vertical Thin Bodies Field-Effect Transistor with multiple MOS structures and 1.5 nm body width for each of the vertical thin bodies 201B1, 201B2 and 201B3, and 1 nm thickness gate oxide (high-k dielectric layer 217D) covering the vertical thin bodies 201B1, 201B2 and 201B3. Between two of the vertical thin bodies 201B1, 201B2 and 201B3, there is metal conductive pole (a portion of the gate conductive layer 217E) made of suitable metal. With suitable gate metal material (work function layer 217F) to adjust the work function of the conductive pole and/or the gate conductive material (the gate conductive layer 217E), lon of the transistor structure 20 is around 3 times of that of the conventional FinFET 30, and loff of the transistor structure 20 is around 33% (reduced 67%) of that of the conventional FinFET 30. It is noticed that, due to the vertical thin bodies 201B1, 201B2 and 201B3, there are multiple current conductive channels in the new the transistor structure 20 to increase lon. On the other hand, the existence of the conductive poles could reduce loff. Therefore, the transistor structure 20 provided by the present invention effectively improve the lon/loff ratio about 10 times, as compared with the convention FinFET 30. Thus, the lon/loff ratio is greater than 1˜4×10⁶, and loff current is less than 100, 80, or 50 pA.

As shown in FIG. 3, based on the same structure (i.e. the same fin height), the current density during the Off-state of the conventional FinFET 30 is 3 times of that of the transistor structure 20 provided by the present invention; and the current density during the On-state of the transistor structure 20 provided by the present invention is 5 times of that of the conventional FinFET 30.

In summary, there are more than 2 vertical thin semiconductor bodies (e.g., three vertical thin bodies 201B1, 201B2 and 201B3) in one convex structure (e.g. the semiconductor convex structure 201F) of the transistor structure 20 according to one embodiment of the present invention, and one conductive central pole (a portion of the gate conductive layer 217E) is inserted between two adjacent vertical thin semiconductor bodies (e.g., adjacent two of three vertical thin bodies 201B1, 201B2 and 201B3). Such conductive metal poles in the single convex structure of the transistor can effectively suppress the leakage current path during the off state of the 6CFET (transistor structure 20) However, the 6CFET has more than two vertical thin bodies (the vertical thin bodies 201B1, 201B2 and 201B3) for current conduction during the ON state. The width of each of the vertical thin bodies 201B1, 201B2 and 201B3 could be around 5 nm to 0.7 nm, such as, 3 nm, 2 nm, 1.5 nm, 1 nm, or 0.7 nm, for example.

Moreover, a solid wall (such as, the dielectric spacer 203N and the thin thermal oxide layer 203O) is formed to clamp the active region or the narrow convex structure (the semiconductor convex structure 201F), especially the sidewalls of the convex structure. The solid clamping wall could be a single layer or other composite layers to protect the narrow convex structure from collapse during the forming the source/drain region 212S/212D or gate structure 217. Furthermore, the thick oxide layer or STI layer (e.g. the STI region and the low-K material spacer 222) further encompass or clamp the active region or the narrow convex structure (the semiconductor convex structure 201F), especially the sidewalls of the convex structure, to protect the narrow Convex structure from collapse during the forming the source/drain region 212S/212D or gate structure 217. Thus, even the height of the convex structure (such as, 60 nm to 300 nm) is far larger than the width of the convex structure (such as, 3 nm to 7 nm), the convex structure protected by the sold wall of the present invention is unlikely vulnerable during the following processes (such as, the source/drain region 212S/212D or formation, the gate structure 217 formation, etc.).

Another advantage of the present invention is that, since the thickness of the oxidation layer 215 made by an oxidation process is controllable, the edge of the source/drain region 212S/212D could be aligned or substantially aligned with the edge of the gate region (e.g. the gate structure 217), especially the source/drain region 212S/212D is formed by SEG. Thus, according to the present invention, the relative position or distance between the edge of the dummy gate 209 and the edge of the gate structure 217 is controllable, and could be dependent on the thickness of the spacer (e.g. the thickness of the low-k spacer 213) formed on the edges of the gate structure 217 and/or the thickness of the oxidation layer 215. Therefore, the effective channel length (Leff) could be controlled such that the GIDL issue could be improved.

### Advantages

According to the present invention:
(1) The leakage current path during the off state is reduced, due to the existence of conductive central pole (a portion of the gate conductive layer 217E) in the convex structure (the semiconductor convex structure 201F), and such a conductive Central Pole within the Convex structure can effectively suppress the leakage current path during the off state of the transistor structure 20, and increase the conductive current during the on state of the transistor structure 20.
(2) By using a process with a minimum feature size of a 5 nm, a new Vertical Thin Body Field-Effect Transistor with multiple MOS structures and multiple conductive channels has its structure having the following dimensions: each of the three vertical thin body (e.g. the vertical thin bodies 201B1, 201B2 and 201B3) has the width of 1.5 nm, the gate dielectric thickness of 1 nm on both sides of the vertical thin body, the conductive metal pole has width of around 5 nm, thus requiring the starting convex thickness about 26.5 nm. By assuming the STI width between the convex is 8 nm, then the pitch (space plus width) of the Vertical Thin Body Field-Effect Transistor is 28.5 nm (=3.5×3+5×2+8, which is around 5.7 F), which is still smaller than the pitch of a state-of-the-art FinFET which has a Fin width of 6 nm and the space between two Fins is 24 nm, thus such a transistor pitch is 30 nm (=6 F).
(3) According to the device simulation results of the 6 C Vertical Thin Body Field-Effect Transistor (the transistor structure 20) versus the conventional FinFET 30. The transistor structure 20 of the present invention effectively improve the lon/loff ratio about 10 times, as compared with the convention FinFET 30. So the productivity of the Vertical Thin Body Field-Effect Transistor is really much better and worthwhile for executing the new structure with quite affordable processing complexity.
(4) A solid wall (such as, the dielectric spacer 203N and the thin thermal oxide layer 203O) is formed to clamp the active region or the narrow Convex structure (the semiconductor convex structure 201F), especially the sidewalls of the convex structure. Thus, even the height of the Convex structure is far larger than the width of the Convex structure, the Convex structure protected by the sold wall of the present invention is unlikely vulnerable.
(5) The relative position or distance between the edge of the source/drain region 212S/212D and the edge of the gate structure 217 is controllable, and could be dependent on the thickness of the spacer (e.g. the thickness of the low-k spacer 213) formed on the edges of the gate structure 217 and/or the thickness of the oxide layer (such as, the oxidation layer 215).
(6) The resistance of the Source/Drain region could be improved by forming metal-semiconductor junction in the Source/Drain region.
(7) Most the source/drain region 212S/212D are isolated by insulation materials including the bottom structure by the oxidation layer 215 and/or bottom nitride layer 218, the junction leakage can be significantly reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A transistor structure, comprising:
a semiconductor substrate with a semiconductor convex structure and an original semiconductor surface, wherein a set of trenches are formed in the semiconductor convex structure; and
a gate structure with a gate conductive layer and a gate dielectric layer, wherein the gate conductive layer is across over the semiconductor convex structure, and a portion of the gate conductive layer is filled in the set of trenches.

2. The transistor structure according to claim 1, wherein a bottom surface and sidewalls of each of the set of trenches are covered by the gate dielectric layer.

3. The transistor structure according to claim 1, wherein a bottom of the gate conductive layer outside the semiconductor convex structure is lower than that of the portion of the gate conductive layer filled in one of the set of trenches.

4. The transistor structure according to claim 1, wherein the semiconductor convex structure comprises a plurality of vertical thin bodies, and the gate dielectric layer is disposed between the gate conductive layer and the plurality of vertical thin bodies.

5. The transistor structure according to claim 1, further comprising:
a source region contacting with a first end of the semiconductor convex structure;
a drain region contacting with a second end of the semiconductor convex structure;
a first concave accommodating the source region; and
a second concave accommodating the drain region;
wherein sidewalls of the first concave and sidewalls of the second concave are surrounded by a STI region.

6. The transistor structure according to claim 5, wherein an edge of the source region contacts with the plurality of vertical thin bodies, and an edge of the drain region contacts with the plurality of vertical thin bodies.

7. The transistor structure according to claim 6, wherein the source region comprises:
an LDD region contacting with the plurality of vertical thin bodies;
a heavily doped region laterally extending from the LDD region; and
a metal region being in the first concave and contacting with a sidewall of the heavily doped region.

8. The transistor structure according to claim 5, further comprising:
an oxide layer positioned in the first concave, wherein the oxide layer comprises a vertical portion and a lateral portion covering a bottom of the first concave; wherein a top surface of the vertical portion is higher than that of the lateral portion.

9. The transistor structure according to claim 4, wherein a width of one of the plurality of vertical thin bodies is not greater than 3 nm.

10. The transistor structure according to claim 4, wherein the set of trenches includes two trenches, and the plurality of vertical thin bodies includes three vertical thin bodies.

11. A transistor structure comprising:
a semiconductor substrate with a semiconductor convex structure which comprises a plurality of upward extending semiconductor bodies, wherein the semiconductor substrate is made of a first semiconductor material; and
a set of trenches formed in the semiconductor convex structure to separate the plurality of upward extending semiconductor bodies;
wherein no STI region is between two adjacent upward extending semiconductor bodies.

12. The transistor structure according to claim 11, wherein a bottom of each of the set of trenches directly contacts with the first semiconductor material.

13. The transistor structure according to claim 11, further comprising:
a source region contacting with the semiconductor convex structure;
a drain region contacting with the semiconductor convex structure; and
a gate region with a gate conductive layer, wherein the gate conductive layer is across over the semiconductor convex structure and filled within the set of trenches, and the source region contacts with each of the plurality of upward extending semiconductor bodies, and the drain region contact with each of the plurality of upward extending bodies.

14. The transistor structure according to claim 11, wherein an lon/loff ratio of the transistor structure is greater than 1×10⁶, and an loff current of the transistor structure is less than 80 pA.

15. A method for fabricating a transistor structure, comprising:
defining at least one semiconductor convex structure surrounded by a shallow trench isolation (STI) region in a semiconductor substrate, wherein the semiconductor convex structure is covered by a first pad dielectric layer;
forming a composited spacer structure on the top of the semiconductor convex structure;
forming a set of trenches in the semiconductor convex structure using portion of the composited spacer structure as an etching mask;
fully filling the set of trenches with a sacrificial material;
forming a dummy gate covering the sacrificial material;
removing the composited spacer structure to expose portions of the semiconductor convex structure;
forming a source region contacting with a first end of the semiconductor convex structure and a drain region contacting with a second end of the semiconductor convex structure; and
forming a gate structure across over the semiconductor convex structure.

16. The method according to claim 15, wherein the forming of the composited spacer structure comprises:
removing the first pad dielectric layer covering a top of the semiconductor convex structure to form an opening for exposing the top of the semiconductor convex structure and partially exposing sidewalls of the STI region; and
a composited spacer structure with at least three spacers constituting by different material are formed and laterally stacked on the exposed portion of the sidewalls of the STI region to fill the opening.

17. The method according to claim 16, wherein the forming of the set of trenches comprises:
forming a second pad dielectric layer covering the composited spacer structure;
patterning the second pad dielectric layer to define a through hole passing through the second pad dielectric layer to expose a portion of the composited spacer structure;
forming a mask spacer on sidewalls of the through hole for exposing at least two of the at least three spacers;
using the patterned second pad dielectric layer and the mask spacer as an etching mask to remove portions of the composited spacer structure and the semiconductor convex structure from the through hole to form the set of trenches in the semiconductor convex structure, so as to define a plurality of vertical thin bodies in the semiconductor convex structure.

18. The method according to claim 17, wherein the forming of the source region and the drain region comprises:
removing the patterned second pad dielectric layer and a remained portion of the composited spacer structure to expose portions of the semiconductor convex structure;
removing exposed portions of the semiconductor convex structure to form a source trench and a drain trench in the semiconductor convex in structure;
performing a thermal oxidation process to form an oxidation layer on bottoms and sidewalls of the source trench and the drain trench;
removing a portion of the oxidation layer formed on the sidewalls of the source trench and the drain trench to expose vertical sidewalls of the semiconductor convex structure beneath the dummy electrode;
growing epitaxial semiconductor material based on the exposed vertical sidewalls of the semiconductor convex structure beneath the dummy electrode; and
filling the source trench and the drain trench with a conductive material to contact the epitaxial semiconductor material and form the source region and the drain region.

19. The method according to claim 18, wherein the forming of the gate structure comprises:
removing the dummy electrode and the sacrificial material;
forming a high-k dielectric layer to cover sidewalls of the vertical thin bodies; and
forming a gate conductive layer across over the semiconductor convex structure and filling in the set of trenches.

20. The method according to claim 19, further comprising forming a work function layer to come across over the vertical thin bodies.
